(19) United States
(12) Patent Application Publication
(10) Pub. No.: US 2025/0338662 A1
(43) Pub. Date: Oct. 30, 2025

(54) TWO LAYER PIXEL STRUCTURE FOR HIGH RESOLUTION WITH HIGH DYNAMIC RANGE

(71) Applicant: Taiwan Semiconductor Manufacturing Company, Ltd., Hsinchu (TW)

(72) Inventors: Chieh-En Chen, Tainan City (TW); Chen-Hsien Lin, Tainan City (TW); Shyh-Fann Ting, Tainan City (TW)

(21) Appl. No.: 19/263,581

(22) Filed: Jul. 9, 2025

Related U.S. Application Data
(63) Continuation of application No. 18/739,473, filed on Jun. 11, 2024.
(60) Provisional application No. 63/558,147, filed on Feb. 27, 2024.

(51) Int. Cl. H10F 39/00; H10F 39/18

(52) U.S. Cl. CPC H10F 39/809; H10F 39/182; H10F 39/8037

(57) ABSTRACT

An image sensor achieves high pixel density, and therefore high resolution, by offloading portions of a photodetector circuit to a separate device layer from the photodiodes. The photodetector uses a lateral overflow integration capacitor and a dual conversion gain transistor to increase dynamic range. The dynamic range is further increased by providing a high conversion gain mode in which the floating diffusion node is isolated from the second device layer and from the wiring that extends to the second device layer. This is accomplished by disposing the DCG transistor and the source follower in the first device layer which has the photodiodes, the transfer gates, and the floating diffusion regions. Isolating the floating diffusion node from the wiring to the second device layer in the high conversion gain mode reduces the capacitance of the floating diffusion node in the high conversion gain mode, and so increases the dynamic range.

### REFERENCE TO RELATED APPLICATIONS

This Application is a Continuation of U.S. application Ser. No. 18/739,473, filed on Jun. 11, 2024, which claims the benefit of U.S. Provisional Application No. 63/558,147, filed on Feb. 27, 2024. The contents of the above-referenced Patent Applications are hereby incorporated by reference in their entirety.

### BACKGROUND

Many modern day electronic devices (e.g., digital cameras, optical imaging devices, etc.) comprise image sensors. An image sensor includes an array of photosensitive areas which are operative as transducers that convert light into electrical charges. Examples of image sensors include charge-coupled device (CCD) image sensors and complementary metal-oxide-semiconductor (CMOS) image sensors. Compared to CCD image sensors, CMOS image sensors are favored due to low power consumption, small size, fast data processing, a direct output of data, and low manufacturing cost.

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIG. 1 illustrates a three-layer device in accordance with some embodiments.

FIG. 2 provides a circuit diagram for an image sensor according to a first embodiment.

FIG. 3 illustrates a plan view of the first device layer in an image sensor in accordance with the first embodiment.

FIG. 4 provides a perspective view corresponding to FIG. 3.

FIG. 5 illustrates a plan view of the second device layer in an image sensor in accordance with the first embodiment.

FIG. 6 provides a perspective view corresponding to FIG. 5.

FIG. 7 provide a perspective view showing the first device layer and the second device layer together in accordance with the first embodiment.

FIG. 8 provides a circuit diagram for an image sensor according to a second embodiment.

FIG. 9 illustrates a plan view of the first device layer in an image sensor in accordance with the second embodiment.

FIG. 10 illustrates a plan view of the second device layer in an image sensor in accordance with the second embodiment.

FIG. 11 provides a circuit diagram for an image sensor according to a third embodiment.

FIG. 12 illustrates a plan view of the first device layer in an image sensor in accordance with the third embodiment.

FIG. 13 illustrates a plan view of the second device layer in an image sensor in accordance with the third embodiment.

FIGS. 14-21 provide a series of cross-sectional views illustrating an embodiment of a manufacturing process applied to the first device layer.

FIG. 22 provides a plan view corresponding to FIG. 21.

FIGS. 23-32 provide a series of cross-sectional views illustrating an embodiment of a manufacturing process applied to the second device layer.

FIG. 33 provides a plan view corresponding to FIG. 32.

FIGS. 34A-39 provide a series of cross-sectional views illustrating the joining of the first, second and third device layers and further manufacturing applied to the first device layer in accordance with an embodiment.

FIGS. 40 is a flow chart of a process in accordance with some embodiments.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

One type of CMOS image sensor has an array of photodetectors each of which includes at least one photosensitive area within a semiconductor substrate, a transfer gate, a floating diffusion node, a source follower, a row select transistor, and a reset transistor. When the reset transistor is closed, the floating diffusion node is charged to a reference voltage. Light is transduced into electrical charges within the photosensitive area(s). The charges accumulate until the transfer gate is closed allowing them to flow to the floating diffusion node. The charges alter the floating diffusion node voltage. The floating diffusion node is coupled to a gate electrode of the source follower. The source follower is connected in series with the row select transistor. When the row select transistor is closed, current flows through the source follower and the row select transistor. The magnitude of that current depends on the floating diffusion node voltage that is applied to the source follower gate electrode. The current is detected and used to infer the amount of charge that was transferred to the floating diffusion node, which in turn reflects the amount of radiation that was incident on the photosensitive area(s) over a sampling interval.

Conversion gain is a significant parameter in a CMOS image sensor of the type just described. The conversion gain is related to the capacitance of the floating diffusion node. The capacitance of the floating diffusion node includes contributions from a floating diffusion region, which is the drain region of the transfer gate, the source region of the reset transistor, the gate electrode of the source follower, and the wiring that connects these structures. If the capacitance of the floating diffusion node is too low (conversion gain too high) for a given lighting condition and sampling rate, the photodetector will experience saturation so that variations in light intensity at the high end will be lost. If the capacitance is too high (conversion gain too low), there will be excessive noise in the voltage signal and variations in light intensity at the low end will be lost.

One approach to widening the range of lighting conditions over which the photodetector can be effective (increasing dynamic range) involves adding a dual conversion gain (DCG) transistor to the photodetector circuit. The DCG transistor allows the photodetector to be switched between a low conversion gain mode and a high conversion gain mode. In the low conversion gain mode, the DCG transistor is closed so that a capacitor (commonly referred to as a lateral overflow integration capacitor) is coupled to the floating diffusion node through the DCG transistor. In the high conversion gain mode, the DCG transistor is open so that the lateral overflow integration capacitor (LOFIC) is isolated from the floating diffusion node.

Another significant performance parameter for a CMOS image sensor is resolution. High resolution is achieved through high pixel density. The chip area occupied by the transistors in the photodetector circuit can limit pixel density. One approach to overcoming that limitation is a two- or three-device layer approach in which the photodetector transistors (with the exception of the transfer gate) and the LOFIC are disposed on a second die. A shortcoming of this approach is that the wiring that connects the floating diffusion node to the second die adds capacitance to the floating diffusion node even in the high conversion gain mode. That extra capacitance reduces conversion gain and so increases noise and lowers dynamic range.

In accordance with the present disclosure, the problem of providing high resolution with high dynamic range is solved using a two- or three-device layer system in which the floating diffusion node is isolated from the wiring to the second die in the high conversion gain mode. This is accomplished by disposing the DCG transistor and the source follower on the first die together with the photosensitive area, the transfer gate, and the floating diffusion region. Some or all of the remaining photodetector circuit components are disposed on the second die so that high pixel density may still be achieved.

In some embodiments, the DCG transistor, the source follower, and other photodetector circuit components are shared so that there is one DCG transistor and one source follower for every four transfer gates and photosensitive regions. This type of sharing allows pixel density to be increased. The sharing arrangement entails uniting the floating diffusion regions corresponding to the four transfer gates into one floating diffusion node. This would seem to increase the capacitance of the floating diffusion node, however, under very low light conditions, when high conversion gain is at a premium, the four photodetector pixels may be operated as one large pixel. That operation mode increases full well capacity and provides higher dynamic range.

An image sensor according to the present disclosure may have a very large difference in conversion gain between the low conversion gain mode and the high conversion gain mode. In some embodiments, the photodetector includes a second DCG transistor and a second LOFIC so that there may be an intermediate conversion gain mode between the low conversion gain mode and the high conversion gain mode. The intermediate conversion gain mode may be used to provide a smoother transition from the low conversion gain mode to the high conversion gain mode. Alternatively, the intermediate conversion gain mode may take the place of the high conversion gain mode, and the high conversion gain mode may become a very high conversion gain mode so that the dynamic range is further increased.

In some embodiments, the source follower and the dual conversion gain transistor are aligned in a row. The four photosensitive areas that share the source follower and the dual conversion gain transistor may be arranged two on each side of the row. In some embodiments, each pair of transfer gates share a floating diffusion region, which is an area of the substrate on the drain side of the respective transfer gate. The DCG transistor and the source follower may be isolated from the floating diffusion regions and the photosensitive areas by shallow trench isolation structures. Wiring associated with the floating diffusion node may be limited to four contact plugs and interconnecting wiring in a metallization layer (the M1 metallization layer) nearest the substrate. The four contact plugs may include one contact plug for each of the two floating diffusion region, one contact plug for the source follower gate electrode, and one contact plug for the DCG transistor source region. All of these contact plugs may be coupled with two short wiring segments in the M1 metallization layer. Wiring in the M2 and higher metallization layers may be avoided. This structure limits the wiring connected to the floating diffusion node in the high conversion gain mode and thereby increases dynamic range.

The first DCG and the second DCG may be connected in series and the first LOFIC may be connected to the first DCG in parallel with the second DCG. Closing the first DCG adds the first LOFIC to the floating diffusion node. Closing the second DCG in addition to the first DCG brings the second LOFIC into the floating diffusion node. In some embodiments, the first LOFIC is on the first die and the second LOFIC is on the second die. This arrangement allows the first LOFIC and the second LOFIC to each have a large area. Both the first LOFIC and the second LOFIC may be three-dimensional metal-insulator-metal (3DMIM) capacitors.

In some embodiments, each photodetector includes two connections between the first die and the second die. The first connection may be between the DCG transistor on the first die and an LOFIC or a reset transistor on the second die. The second connection may be between the source follower on the first die and a row select transistor on the second die. In some embodiments, the first and second connections form first rows, each first row comprising alternating first and second connections extending across the photodetector array. The first and second connection are made through bond pads on the first die. In some embodiments, dummy contact pads are disposed in second rows interleaved with the first rows. The dummy contact pads facilitate manufacturing. In some embodiments Vdd rails extend parallel to the first rows between the first rows. These Vdd rail positions avoid inductive coupling. In some embodiments, LOFIC capacitors are disposed directly below the Vdd rails.

In some embodiments, the second die has corresponding rows of bond pads and dummy contact pads. In some embodiments, the second die has Vdd rails extending parallel to the first rows between the first rows. In some embodiments, the second die has LOFIC capacitors disposed directly above the Vdd rails so that the LOFIC capacitors are between the Vdd rails and the substrate of the second die.

In some embodiments, the image sensor includes a third die. The third die may be in a stacked arrangement with the first die and the second die. The third die may contain an application specific integrated circuit (ASIC). The ASIC uses data from the photodetector array and may contain components such as memory cells, logic circuits, and the like. Placing this additional circuitry on the third die preserves the image sensing area on the first die and leaves more area for in-pixel circuitry on the second die.

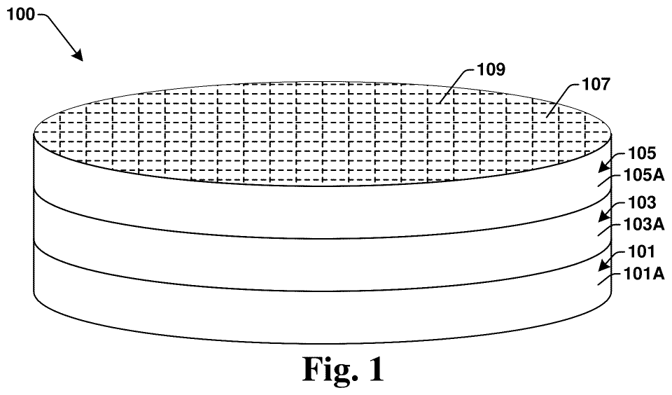

FIG. 1 illustrates a perspective view of an integrated circuit device 100 in accordance with some embodiments. The integrated circuit device 100 includes three device layers: a first wafer 101A comprising first dies 101, a second wafer 103A comprising second dies 103, and a third wafer 105A comprising third dies 105. The first dies 101 and the second dies 103 include photodetector components. The third dies 105 may provide application specific integrated circuit (ASIC). After dicing along scribe lines 109 and then packaging, the integrated circuit device 100 provides image sensors 107 each of which includes a first die 101, a second die 102, and a third die 105.

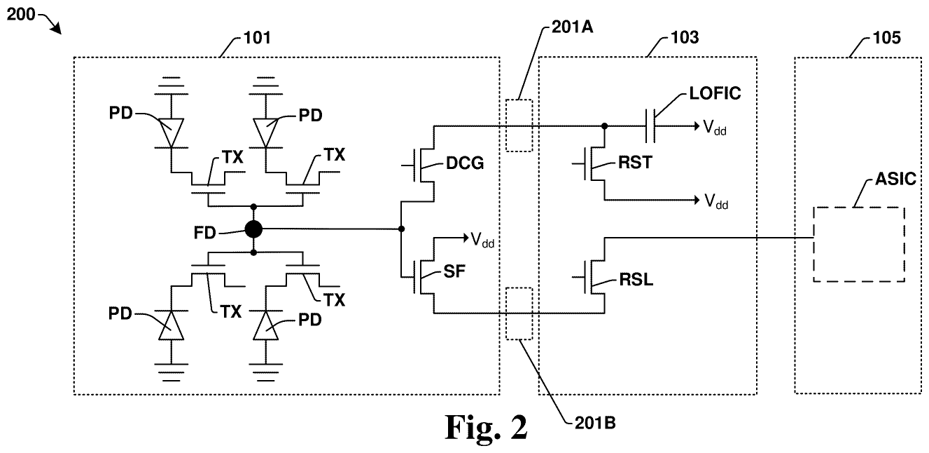

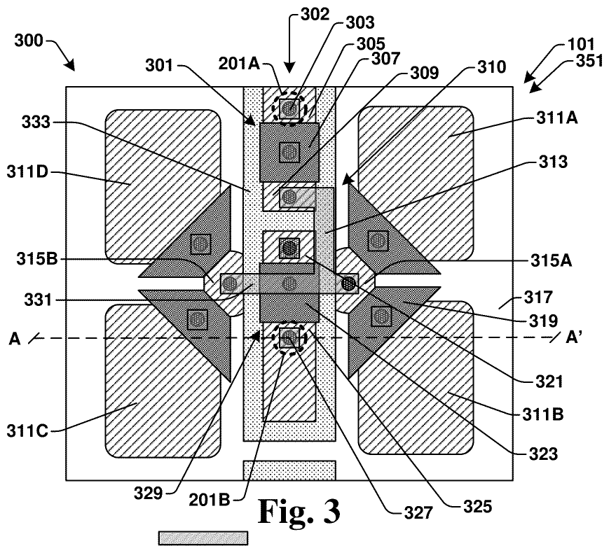

FIG. 2 provides a circuit diagram 200 for a photodetector that may be one in an array of photodetectors in the image sensor 107. The photodetector includes four photodiodes PD, four transfer gates TX, a DCG transistor, and a source follower SF on the first die 101. The four photodiodes PD are coupled to a floating diffusion node FD through four respective transfer gates TX. A gate of the source follower SF and the source side of the DCG transistor are also connected to the floating diffusion node FD.

The photodetector further includes a reset transistor RST, a row select transistor RSL, and a LOFIC on the second die 103. The source side of the reset transistor RST is coupled to the drain side of the DCG transistor through a first connection structure 201A. Closing the DCG transistor adds the capacitance of the first connection structure 201A and related wiring as well as the capacitance of the LOFIC to the floating diffusion node FD. The drain side of the row select transistor RSL is coupled to the source side of the source follower SF through a second connection structure 201B. The source side of the row select transistor RSL may be coupled to an ASIC on the third die 105. The ASIC is not considered part of the photodetector.

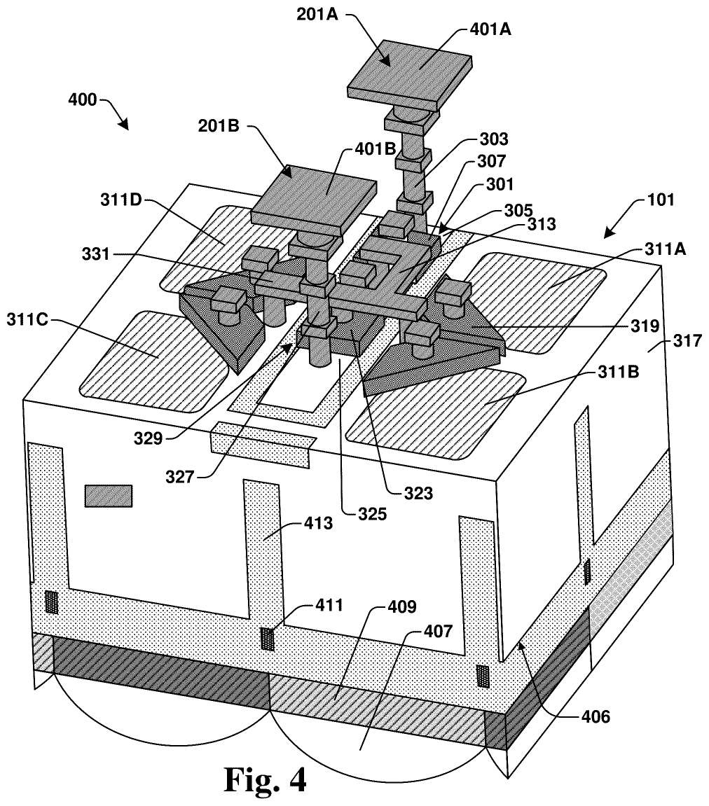

FIG. 3 provides a plan view 300 and FIG. 4 provides a perspective view 400 of an area on the first die 101 containing a portion of a photodetector 351 that is on the first die 101. The photodetector 351 corresponds with the circuit diagram 200 of FIG. 2. Referring to the plan view 300 of FIG. 3, the photodetector 351 includes photodiodes 311A-D in the first die 101. The photodiodes 311A-D are photosensitive areas in a semiconductor substrate 317, which is part of the first die 101. The photodiodes 311A and 311B are selectively couple to a first floating diffusion region 315A through a first pair of transfer gates 319. The photodiodes 311C and 311D are selectively coupled to a second floating diffusion region 315B through a second pair of transfer gates 319. The first floating diffusion region 315A and the second floating diffusion region 315B are doped areas of the semiconductor substrate 317.

A DCG transistor 301 and a source follower 329 are arranged end to end in a row 302. The photodiodes 311A and 311B are on one side of the row 302, and the photodiodes 311C and 311D are on the opposite side of the row 302. The DCG transistor 301 and the source follower 329 are isolated from one another, from the floating diffusion regions 315A-B, and from the photodiodes 311A-D by segments of a shallow trench isolation structure 333. The DCG transistor 301 includes a DCG source region 309, a DCG drain region 305, and a DCG gate electrode 307. The source follower 329 includes a source follower source region 325, a source follower drain region 321, and a source follower gate electrode 323.

Wiring in the first metallization layer over the semiconductor substrate 317 connects the first floating diffusion region 315A, the second floating diffusion region 315B, the source follower gate electrode 323, and the DCG source region 309 to provide a floating diffusion node 310. The wiring includes a straight wire 331 that connects the first floating diffusion region 315A, the source follower gate electrode 323, and the second floating diffusion region 315B, and an L-shaped wire 313 that connects the straight wire 331 to the DCG source region 309.

With reference to the perspective view 400 of FIG. 4, a first column of metal 303 connects the DCG drain region 305 to a contact pad 401A. The contact pad 401A is part of the first connection structure 201A (see FIG. 2). A second column of metal 327 connects the source follower source region 325 to a contact pad 401B, which is part of the second connection structure 201B.

The perspective view 400 of FIG. 4 is also a cutaway view and thereby shows some of the structures within and on the back side 406 of the semiconductor substrate 317. These include a back side deep trench isolation structure 413 that provides electrical isolation between adjacent photodiodes 311A-D. A back side metal grid 411 increases optical isolation between adjacent photodiodes 311A-D. Color filters 409 and microlenses 407 may also be disposed on the back side 406.

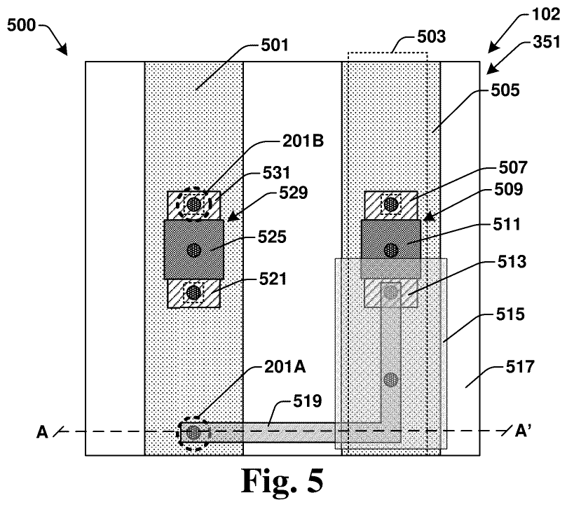

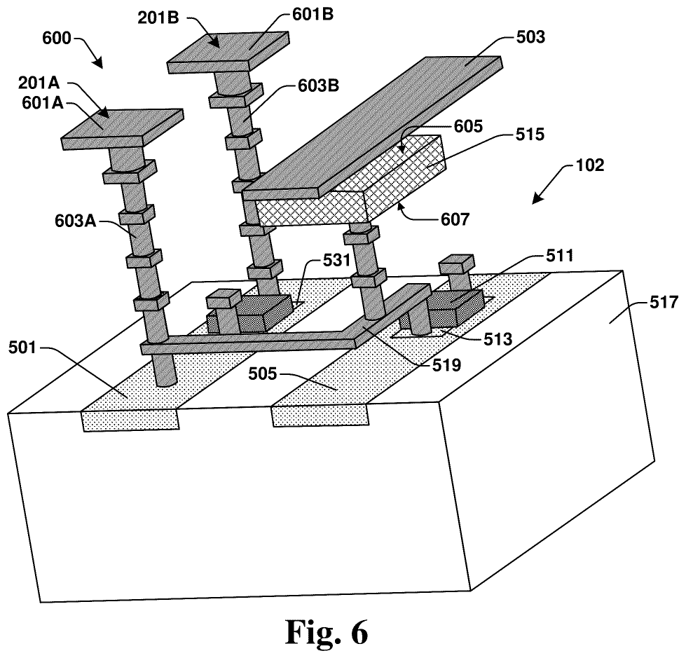

FIG. 5 provides a plan view 500 and FIG. 6 provides a perspective view 600 of an area on the second die 103 that contains a second portion of the photodetector 351. Referring to the plan view 500 of FIG. 5, the second die 103 includes a semiconductor substrate 517. A reset transistor 509 and a row select transistor 529 are formed on the semiconductor substrate 517 and are surrounded by isolations structures 505 and 501 respectively. The reset transistor 509 includes a reset transistor source region 513, a reset transistor gate electrode 511, and a reset transistor drain region 507. The row select transistor 529 includes a row select transistor source region 521, a row select transistor gate electrode 525, and a row select transistor drain region 531. An LOFIC 515 is disposed over the semiconductor substrate 517 and a V_{dd} rail 503 is disposed over the LOFIC 515.

With reference to the perspective view 600 of FIG. 6, a first column of metal 603A and a wire 519 connect the reset transistor source region 513 and a bottom electrode 607 of the LOFIC 515 to a contact pad 601A, which is part of the first connection structure 201A (see FIG. 2). A second column of metal 603B connects the row select transistor drain region 531 to a contact pad 601B, which is part of the second connection structure 201B.

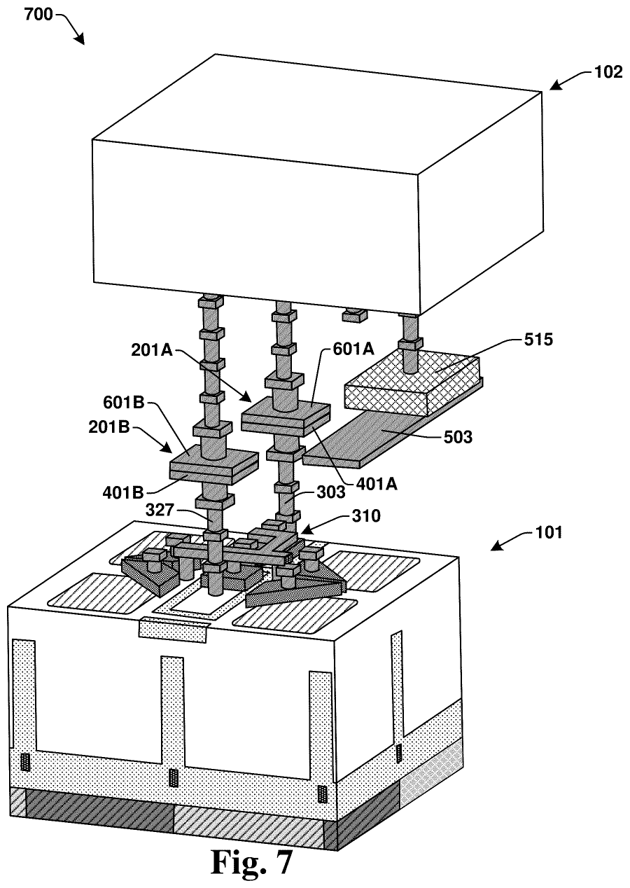

FIG. 7 provides a perspective view 700 showing how the first die 101 is coupled to the second die 103. In particular, the contact pad 401A abuts the contact pad 601A to form the first connection structure 201A and the contact pad 401B abuts the contact pad 601B to form the second connection structure 201B. It can also be seen from the perspective view 700 that the first column of metal 303, the second column of metal 327, and the connection structures 201A and 201B can be electrically isolated from the floating diffusion node 310.

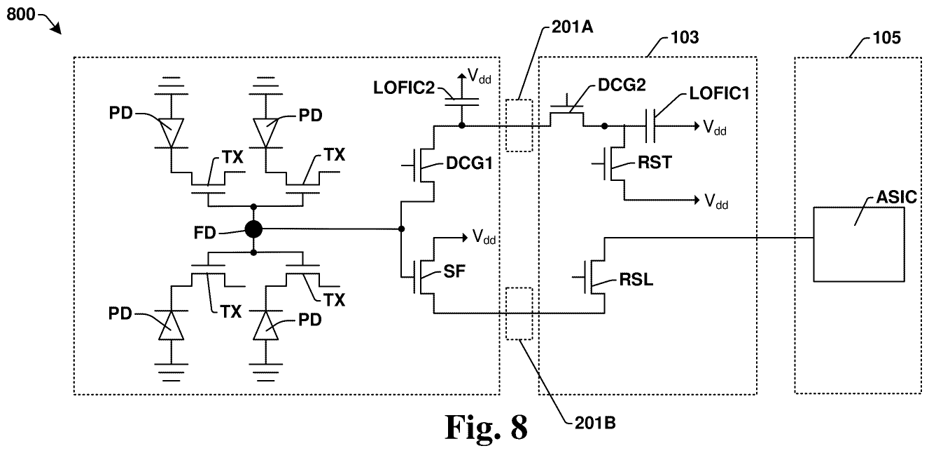

FIG. 8 provides a circuit diagram 800 for another photodetector that may be used in the image sensor 107. The circuit diagram 800 is like the circuit diagram 200 of FIG. 2 except that in the circuit diagram 800 a second LOFIC (LOFIC2) is provided in the first die 101 and a second DCG transistor (DCGG2) is provided in the second die 102. Closing the DCG1 transistor adds the second LOFIC to the floating diffusion node FD and closing both the DCG1 transistor and the DCG2 transistor adds both the first LOFIC and the second LOFIC to the floating diffusion node FD.

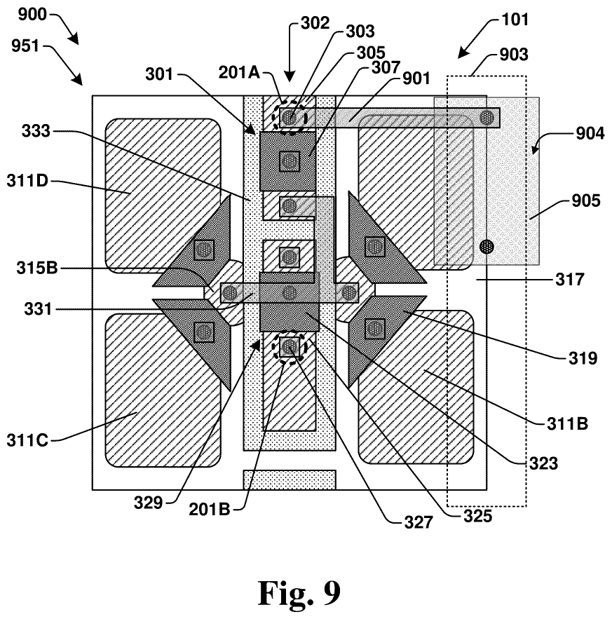

FIG. 9 provides a plan view 900 of an area on the first die 101 containing that portion of a photodetector 951 which is on the first die 101. The photodetector 951 corresponds with the circuit diagram 800 of FIG. 8. The portion of the photodetector 951 that is on the first die 101 is like the portion of the photodetector 351 that would be on the first die 101 (see FIG. 3) except that the photodetector 951 include a second LOFIC 905. A wire 901 connects a bottom electrode (not shown) of the second LOFIC 905 to the first column of metal 303 and the DCG drain region 305. A top electrode 904 of the second LOFIC 905 is connected to a V_{dd} rail 903, which is above the second LOFIC 905 in a metal interconnect structure of the first die 101. The V_{dd} rail 903 may be one in an array of V_{dd} rails 903 interleaved with rows 302.

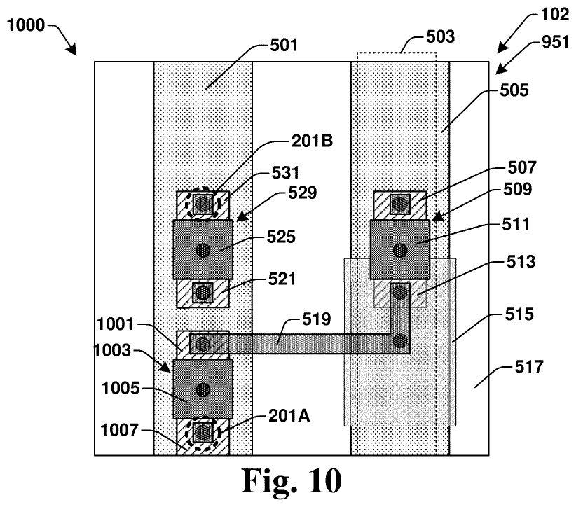

FIG. 10 provides a plan view 1000 of an area on the second die 103 that contains that portion of the photodetector 951 which is on the second die 103. The portion of the photodetector 951 that is on the second die 103 is like the portion of the photodetector 351 that would be on the second die 103 (see FIG. 5) except that the photodetector 951 includes a second DCG 1003 on the second die 103. The second DCG 1003 includes a drain region 1001, a source region 1007, and a gate electrode 1005. Instead of being coupled directly to the first connection structure 201A as it is in the photodetector 351 (see FIG. 5), the wire 519 connects to the first connection structure 201A through the second DCG 1003.

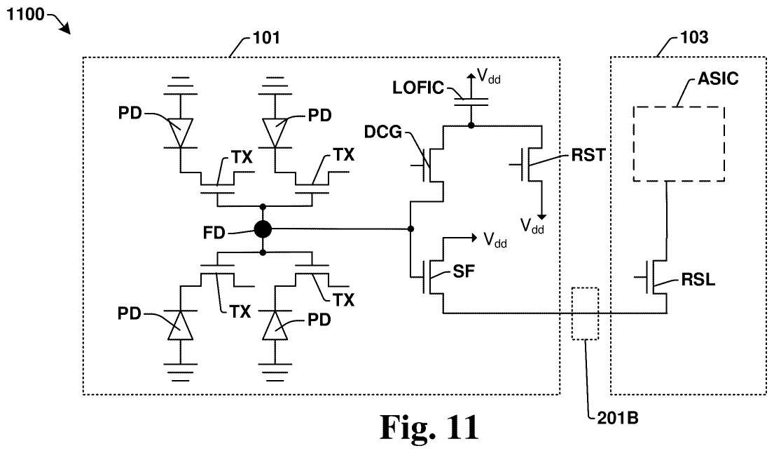

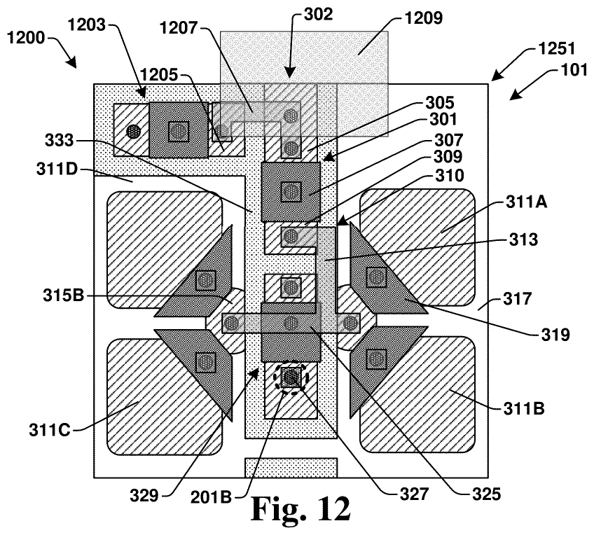

FIG. 11 provides a circuit diagram 1100 for a photodetector according to another embodiment. The circuit diagram 1100 is like the circuit diagram 200 of FIG. 2 except that in the circuit diagram 1100 there is one less connection between the first die 101 and the second die 103 and the LOFIC and the reset transistor RST are on the first die 101. Moving these components to the first die 101 leaves more area on the second die 103 for in-pixel circuitry. The additional area on the second die 103 might alternatively be used to implement the ASIC.

FIG. 12 provides a plan view 1200 of an area on the first die 101 containing a portion of a photodetector 1251 that is on the first die 101. The photodetector 1251 corresponds with the circuit diagram 1100 of FIG. 11. The portion of the photodetector 1251 that is on the first die 101 is like the portion of the photodetector 351 that would be on the first die 101 (see FIG. 3) except that the photodetector 1251 include a reset transistor 1203 and an LOFIC 1209. Moreover, the photodetector 1251 lacks the column of metal 303 (see FIG. 3) and instead contains a wire 1207 coupling the DCG drain region 305 to a source region 1205 of the reset transistor 1203 and to a bottom electrode of the LOFIC 1209. The top electrode of the LOFIC 1209 is connected to a V_{dd} rail (not shown).

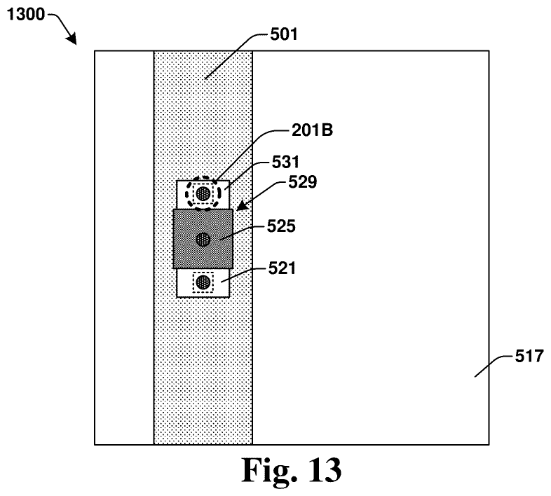

FIG. 13 provides a plan view 1300 of an area on the second die 103 that contains a second portion of the photodetector 1251 that is on the second die 103. The portion of the photodetector 1251 that is on the second die 103 is like the portion of the photodetector 351 that would be on the second die 103 (see FIG. 5) except that the photodetector 951 lacks the reset transistor 509 and the LOFIC 515.

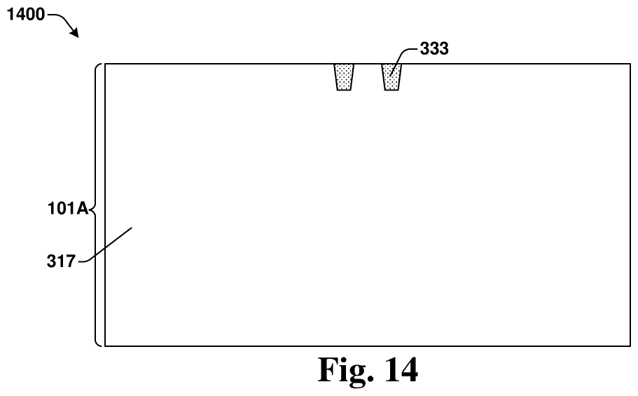

FIGS. 14-39 provide a series of views that illustrate an image sensor according to the present disclosure at various stages of manufacture according to a process of the present disclosure. The cross-sectional views in this series of views may correspond with the line A-A′ in FIGS. 3 and 5. Although FIGS. 14-39 are described in relation to a series of acts, it will be appreciated that the order of the acts may in some cases be altered and that this series of acts are applicable to structures other than the ones illustrated. In some embodiments, some of these acts may be omitted in whole or in part. Furthermore, although FIGS. 14-39 are described in relation to a series of acts, it will be appreciated that the structures shown in FIGS. 14-39 are not limited to a method of manufacture but rather may stand alone as structures separate from the method.

As illustrated by the cross-sectional view 1400 of FIG. 14, the method may begin with forming the shallow trench isolation structures 333 in the semiconductor substrate 317 of the first wafer 101A. The semiconductor substrate 317 may be cut from a single crystal and may be any type of semiconductor. The semiconductor may be, for example, silicon (Si), a group III-V semiconductor or some other binary semiconductor, a tertiary semiconductor (e.g., AlGaAs), a higher order semiconductor, or the like. In some embodiments, the semiconductor substrate 317 is or comprises silicon (Si) or the like. Forming the shallow trench isolation structures 333 may include forming a mask and etching trenches in the semiconductor substrate 317, stripping the mask, depositing a dielectric so as to fill the trenches, and planarizing. The dielectric may be silicon dioxide (SiO₂), the like, or any other suitable dielectric.

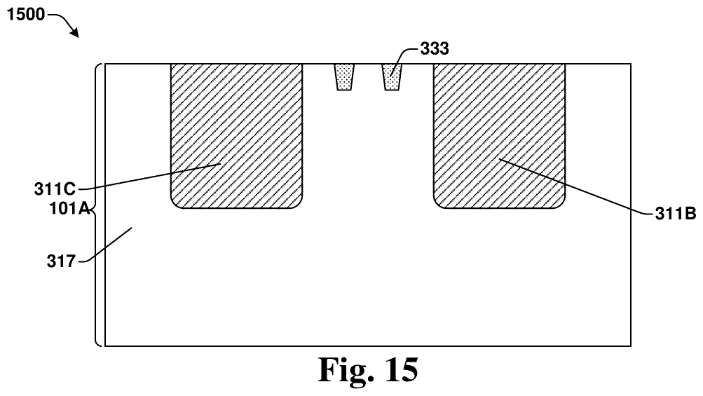

As illustrated by the cross-sectional view 1500 of FIG. 15, the method may continue with implanting dopants to form the photodiodes 311A-D. The dopants may be implanted in a series of steps that include, for example, a deep n-well implant, a shallow p-well implant, and the like. Some of these dopant implants may be carried out with masks and others without. Some of these dopant implants may be carried out before the shallow trench isolation structures 333 are formed.

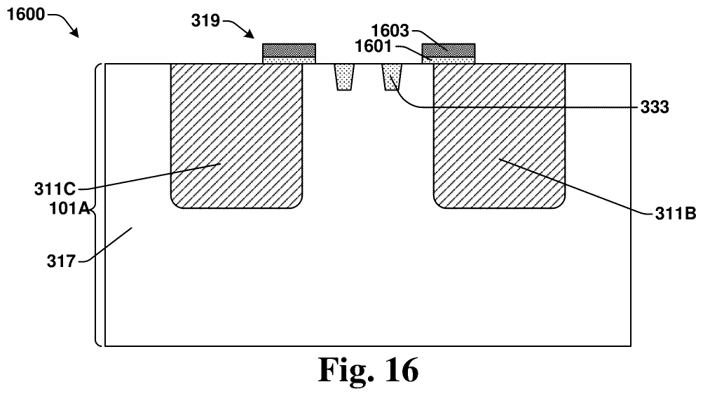

As illustrated by the cross-sectional view 1600 of FIG. 16, transistor gates including gate dielectrics 1601 and gate electrodes 1603 may be formed on the semiconductor substrate 317 in order to provide transfer gates 319 and other transistors. The gate dielectrics 1601 may be an oxide, the like, or some other suitable material. The gate electrodes 1603 may be polysilicon, the like, or some other suitable material. These layers may be deposited by physical vapor deposition (PVD), chemical vapor deposition (CVD), atomic layer deposition (ALD), the like, or any other suitable process. The gate dielectrics 1601 may be formed by oxidation. After deposition, these layers are patterned to define individual gates. Spacers (not shown) are typically formed around the gates. Spacers may be formed by depositing a spacer material followed by anisotropic etching. The spacer material may include one or more layers of any suitable dielectrics. The spacer material may be or comprise, for example, silicon nitride (SiN), silicon oxynitride (SiON), silicon dioxide (SiO₂), a high-K dielectric, or the like. The spacer material may be deposited by ALD, CVD, PVD, the like, or any other suitable process.

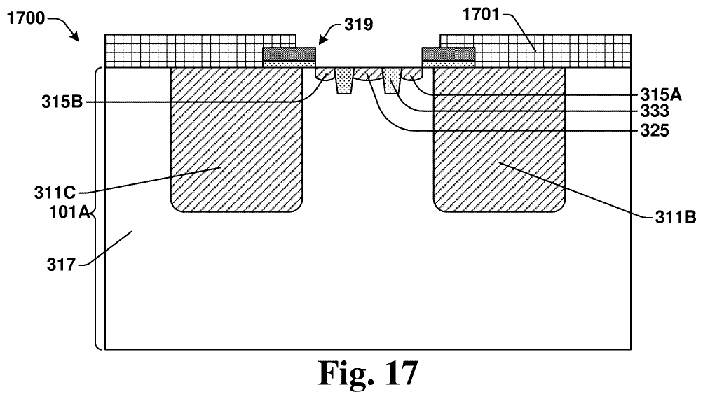

As shown by the cross-sectional view 1700 of FIG. 17, dopants may be implanted to form floating diffusion regions 315A-B, the source follower source region 325, and other source/drain regions. A mask 1701 may be formed prior to implanting the dopants. The floating diffusion regions 315A-B may be aligned to the transfer gates 319 and to the shallow trench isolation structures 333. Alternatively, the floating diffusion regions 315A-B may be spaced apart from the shallow trench isolation structures 333 to reduce leakage currents.

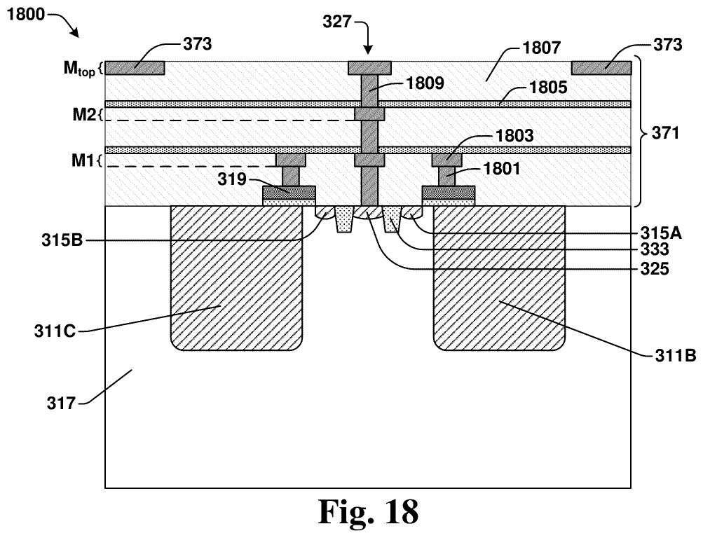

As shown by the cross-sectional view 1800 of FIG. 18, the process may continue with formation of a metal interconnect structure 371. The metal interconnect structure 371 includes a plurality of metallization layers, contact plugs 1801, vias 1809, and a plurality of metallization layers that include wires 1803. The metallization layers include an M1 metallization layer, which is closest to the semiconductor substrate 317, an M2 metallization layer, and an Mₜₒₚ metallization layer, which is uppermost. A greater or lesser number of metallization layers may be included. V_{dd} rails 373 may be disposed in the Mₜₒₚ metallization layer or some other metallization layer.

The contact plugs 1801 may be or comprise tungsten (W), cobalt (Co), cobalt silicide (CoSi2), nickel (Ni), nickel silicide (NiSi), an alloy thereof, the like, or some other suitable material. The wires 1803 and the vias 1809 may be or comprise copper (Cu), tungsten (W), ruthenium (Ru), palladium (Pd), platinum (Pt), cobalt (Co), nickel (Ni), zirconium (Zi), titanium (Ti), tantalum (Ta), aluminum (Al), conductive carbides, oxides, alloys of these metals, the like, or any other suitable conductive materials. The wires 1803 and the vias 1809 may also include a diffusion barrier layer such as titanium (Ti), tantalum (Ta), titanium nitride (TiN), tantalum nitride (TaN), or the like. The metallization layers may be formed by damascene or dual damascene processes. The conductive materials in the metal interconnect structure 371 may be deposited by electroplating, electroless plating, ALD, CVD, PVD, the like, or any other suitable processes.

An interlevel dielectric 1807 surrounds the wires 1803 and the vias 1809. Adjacent metallization layers may be separated by etch stop layers 1805. The interlevel dielectric 1807 may include one or more layers of silicon dioxide (SiO₂), a low-K dielectric, or an extremely low-K dielectric. A low-K dielectric is one having a smaller dielectric constant than silicon dioxide (SiO₂). Silicon dioxide has a dielectric constant of about 3.9. Examples of low-K dielectrics include organosilicate glasses (OSG) such as carbon-doped silicon dioxide, fluorine-doped silicon dioxide (otherwise referred to as fluorinated silica glass (FSG), organic polymer low low-K dielectrics, and porous silicate glass. An extremely low-K dielectric is a material having a dielectric constant of about 2.1 or less. An extremely low-K dielectric material is generally a low-K dielectric material with a porous structure. Porosity reduces the effective dielectric constant. The etch stop layers 1805 may include one or more layers of silicon nitride (SiN), silicon carbide (SiC), silicon carbonitride (SiCN), silicon oxycarbide (SIOC), silicon oxycarbonitiride (SiOCN), combinations thereof, or the like. The interlevel dielectric 1807 and the etch stop layers 1805 may be deposited by ALD, CVD, PVD, the like, or any other suitable processes.

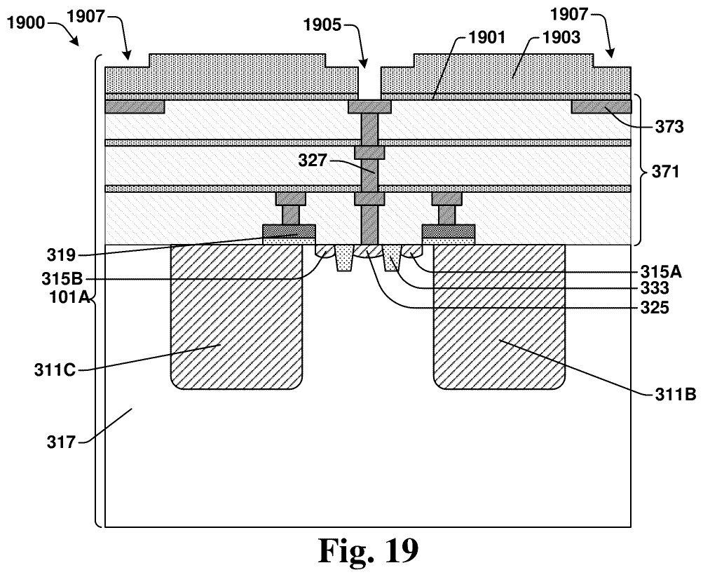

As shown by the cross-sectional views 1900-2100 of FIGS. 19-21, a bonding layer 377 may be formed over the metal interconnect structure 371. As shown by the cross-sectional view 1900 of FIG. 19, formation of the bonding layer 377 may begin with deposition and patterning of an etch stop layer 1901 and a passivation layer 1903. The passivation layer 1903 may include one or more layers of materials such as silicon dioxide (SiO₂), silicon nitride (SiN), the like, or other suitable dielectrics. Openings 1905 and 1907 may be formed by masking and etching.

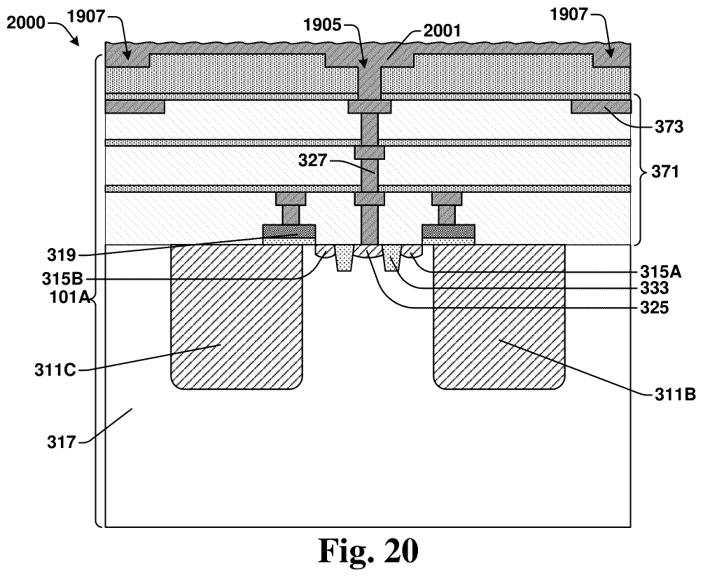

As shown by the cross-sectional view 2000 of FIG. 20, a metal 2001 may be deposited so as to fill the openings 1905 and 1907. The metal 2001 may be or comprise copper (Cu), aluminum (Al), silver (Ag), tin (Sn), Indium (In), nickel (Ni), conductive carbides, oxides, alloys of these metals, the like, or any other suitable materials. The metal 2001 may be deposited by electroplating, electroless plating, ALD, CVD, PVD, the like, or any other suitable processes.

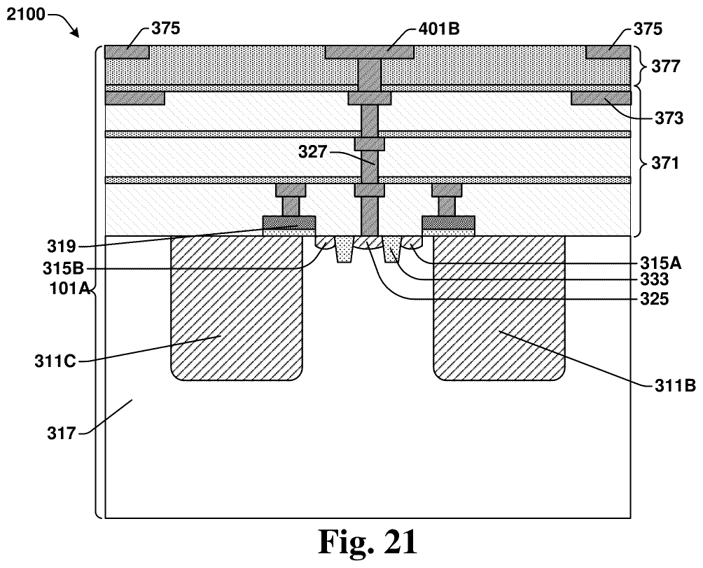

As shown by the cross-sectional view 2100 of FIG. 21 a planarization process may be carried out to remove the metal 2001 that deposited outside the openings 1905 and 1907. The metal 2001 that remains in the openings 1905 provides contact pads 401B and the like. The metal 2001 that remains in the openings 1907 provides dummy contact pads 375. The planarization process may be chemical mechanical polishing (CMP), the like, or some other suitable process.

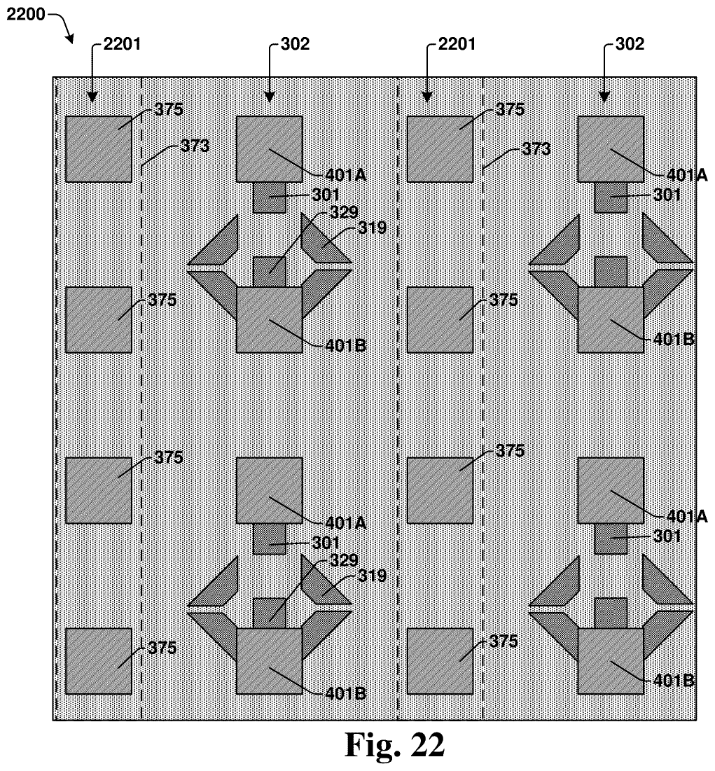

FIG. 22 provides a plan view 2200 corresponding to FIG. 21. As shown by the plan view 2200, the dummy contact pads 375 form rows 2201 between the rows 302 that include the contact pads 401A and 401B. The dummy contact pads 375 combine with the contact pads 401A and 401B to form a regular grid so that the dummy contact pads 375 prevent dishing during the CMP process illustrated by the cross-sectional view 2100 of FIG. 21. The plan view 2200 also shows that the V_{dd} rails 373 run parallel to the rows 302 and are disposed between the rows 302. The extensive coverage of the V_{dd} rails 373 prevents voltage drops that could cause noise. The positioning of the V_{dd} rails 373 avoids noise related to inductive coupling with the wires that connect to the contact pads 401A and 401B.

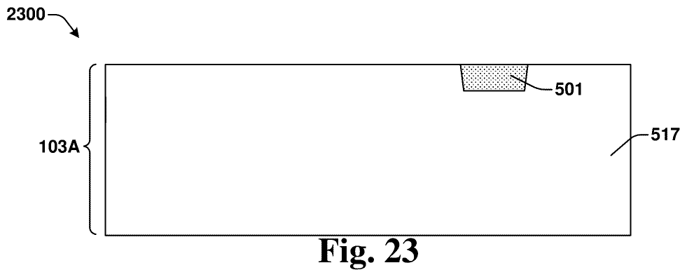

The cross-sectional views 2300 to 3200 of FIGS. 23 to 32 illustrate processing applied to make the second wafer 103A. As shown by the cross-sectional view 2300 of FIG. 23, the processing may begin with forming isolation structures 501 in the semiconductor substrate 517. The semiconductor substrate 517 may have one of the compositions suitable for the semiconductor substrate 317 (see FIG. 14). Transistors may be formed on the semiconductor substrate 517 as they are on the semiconductor substrate 317 (see FIGS. 16 and 17), although none are shown in the cross-sectional views 2300 to 3200 of FIGS. 23 to 32.

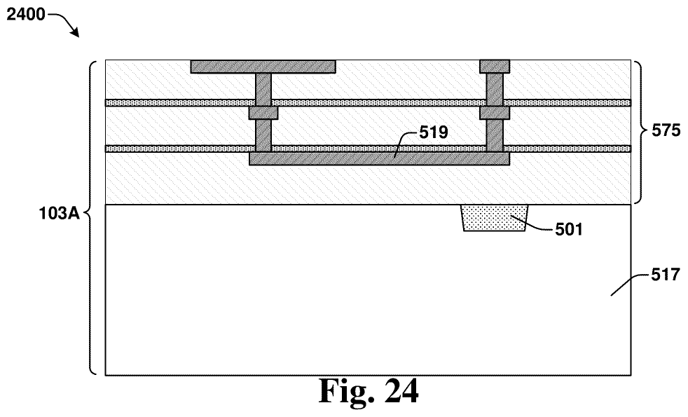

As shown by the cross-sectional view 2400 of FIG. 24, a first group of metallization layers in the metal interconnect structure 575 may be formed over the semiconductor substrate 517. The compositions of these layers and their methods of formation may be as described for the metal interconnect structure 371 in connection with FIG. 18.

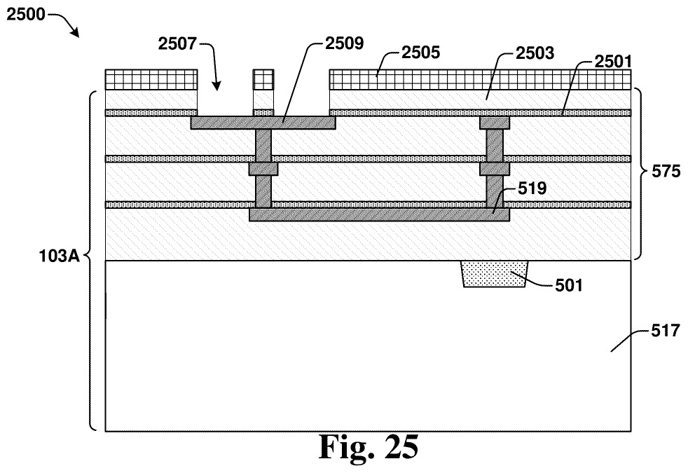

The cross-sectional views 2500 to 3000 of FIGS. 23 to 32 illustrate an example process of forming the LOFIC 515 (see FIG. 6). As shown by the cross-sectional view 2500 of FIG. 25, the process may begin with deposition of an etch stop layer 2501, an interlevel dielectric layer 2503 and a mask 2505. The mask 2505 is patterned and used to etch one or more trenches 2507. A wire 2509 that will be used for a bottom electrode contact may be exposed by the trenches 2507

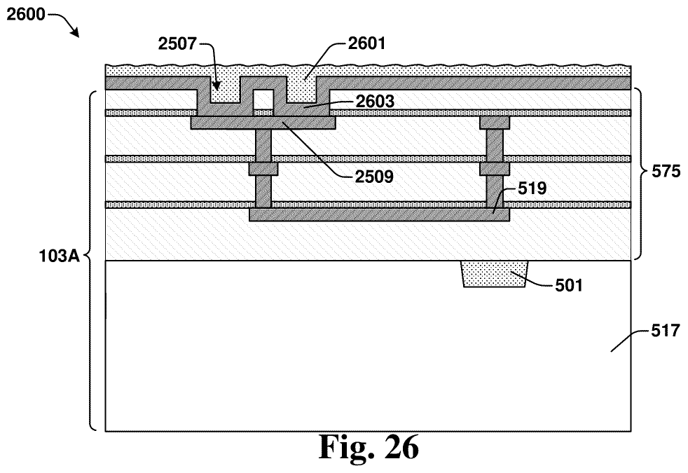

As shown by the cross-sectional view 2600 of FIG. 26, a bottom electrode layer 2603 may be deposited so as to line the trenches 2507 and contact the wire 2509. The bottom electrode layer 2603 may be, for example, titanium nitride (TiN), tungsten (W), titanium (Ti), tantalum (Ta), titanium nitride (TaN), copper (Cu), silver (Ag), aluminum (Al), nickel (Ni), a conductive alloy thereof, or the like. In some embodiments the bottom is titanium nitride (TiN) or the like. Using titanium nitride (TiN) for the electrode metal layer contributes to exceptionally low equivalent series resistance. In some embodiments, the bottom electrode layer 2603 is deposited to a thickness in the range from about 1 nm to about 20 nm. In some embodiments, the bottom electrode layer 2603 is deposited to a thickness in the range from about 20 nm to about 50 nm. Thinner electrode metal layers allow more capacitor plates to be deposited in the trenches 2507 and can provide higher capacitance. Thicker electrode metal layers can reduce equivalent series resistance. The bottom electrode layer 2603 may be deposited by physical vapor deposition (PVD), chemical vapor deposition (CVD), atomic layer deposition (ALD), electroplating, electroless plating, the like, or any other suitable process.

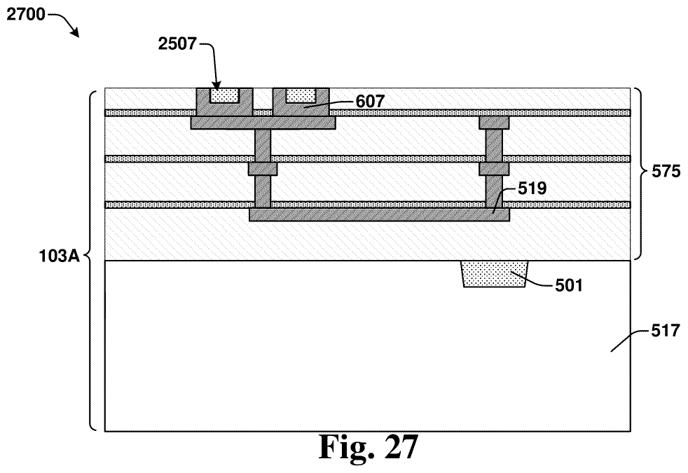

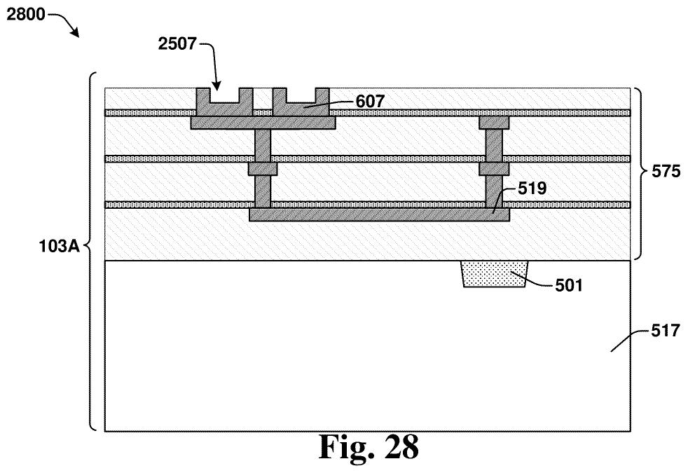

A sacrificial layer 2601 may be deposited over the bottom electrode layer 2603 so as to fill the trenches 2507. The sacrificial layer 2601 may be a bottom antireflective coating (BARC) or any other suitable material. As shown by the cross-sectional view 2700 of FIG. 27, the sacrificial layer 2601 facilitates a planarization process. The planarization process may be CMP or the like and removes portions of the bottom electrode layer 2603 that deposited outside the trenches 2507. A remaining portion of the bottom electrode layer 2603 provides the bottom electrode 607. As shown by the cross-sectional view 2800 of FIG. 28, after planarization the sacrificial layer 2601 may be removed.

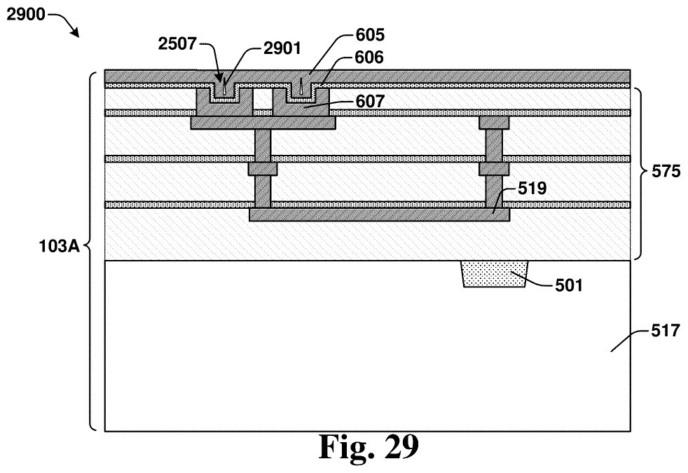

As shown by the cross-sectional view 2900 of FIG. 29, a capacitor dielectric layer 606 and the top electrode 605 may be deposited over the structure shown by the cross-sectional view 2800 of FIG. 28. The capacitor dielectric layer 606 may be any suitable dielectric. In some embodiments, the capacitor dielectric layer 606 is a high-k dielectric. Examples of high-k dielectrics include, without limitation, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), hafnium oxide aluminum oxide (HfO₂—Al₂O₃), zirconium oxide (ZrO₂), tantalum oxide (Ta₂O₅), aluminum oxide (Al₂O₃), yttrium oxide (Y₂O₃), lanthanum oxide (La₂O₃), strontium titanium oxide (SrTiO₃), and the like. The capacitor dielectric layer 606 may be deposited to any suitable thickness. In some embodiments, the capacitor dielectric layer 606 is deposited so as to have a thickness in the range from about 5 nm to about 20 nm. The capacitor dielectric layer 606 may be deposited by ALD, CVD, PVD, the like, or any suitable process. The top electrode 605 may have a composition and thickness as described for the bottom electrode 607.

The cross-sectional view 2900 shows the trenches 2507 being substantially filled by the top electrode 605. Alternatively, the trench sizes any layer thickness may be selected so that additional dielectric layers and electrode layers may be deposited prior to filling the trenches 2507 so that the resulting capacitor may have a greater number of plates than the number illustrated. As the trenches 2507 fill, inclusions 2901 may be formed within the trenches 2507.

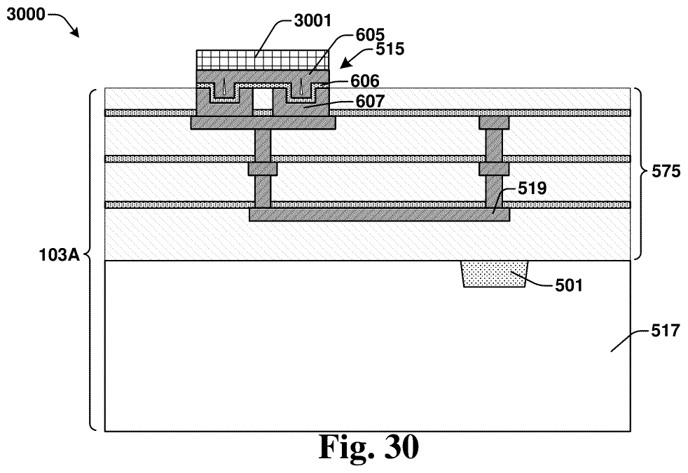

As shown by the cross-sectional view 3000 of FIG. 30, a mask 3001 may be formed and used to pattern the capacitor dielectric layer 606 and the top electrode 605 so as to complete the formation of the LOFIC 515. The LOFIC 515 is a trench-type capacitor, which may also be described as a 3D-MIM capacitor. More generally, the LOFIC 515 may be any suitable type of capacitor.

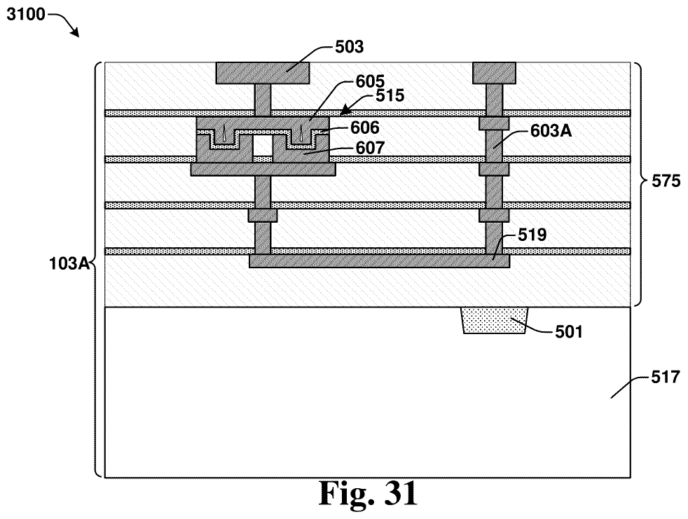

As shown by the cross-sectional view 3100 of FIG. 31, after formation of the LOFIC 515 the formation of the metal interconnect structure 575 may be completed. The metal interconnect structure 575 may include the V_{dd} rail 503. In some embodiments the V_{dd} rail 503 is directly over the LOFIC 515.

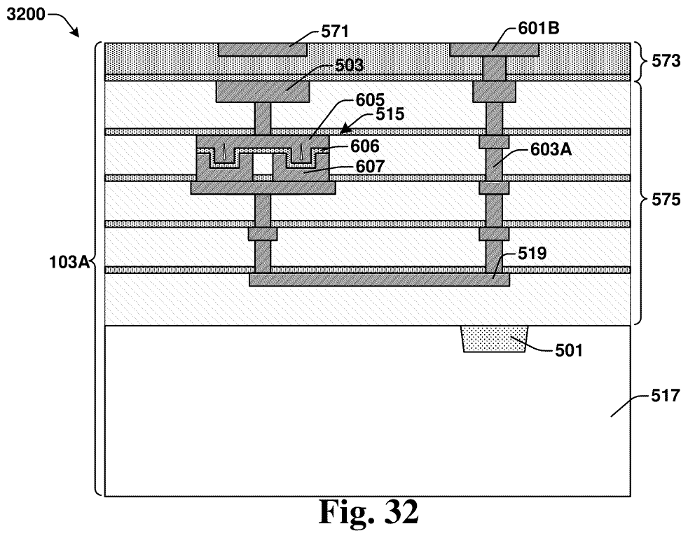

As shown by the cross-sectional view 3200 of FIG. 32, a bonding layer 573 is formed over the metal interconnect structure 575. The bonding layer 573 includes the contact pad 601B and dummy contact pads 571. The formation and composition of the bonding layer 573 may by as described for the bonding layer 377 in connection with FIGS. 19-21.

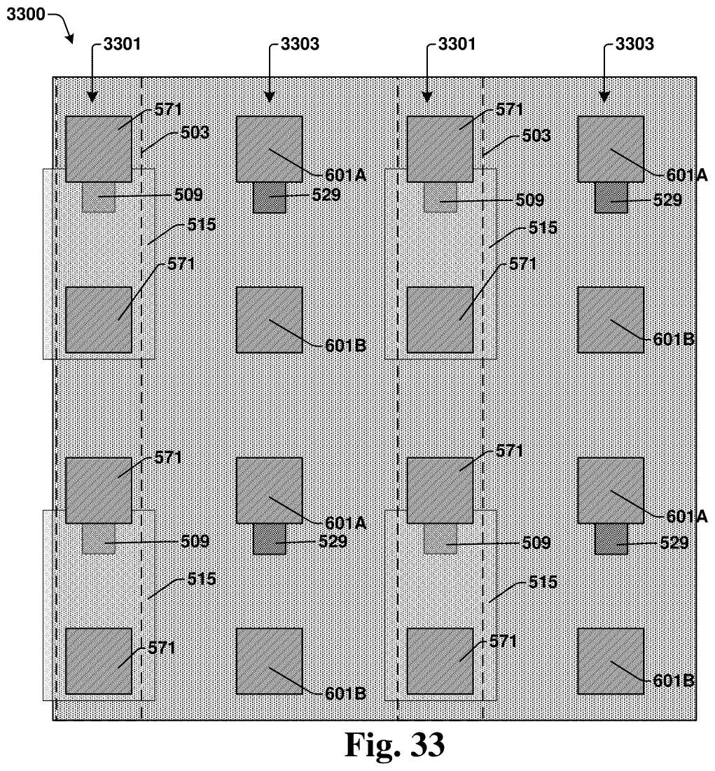

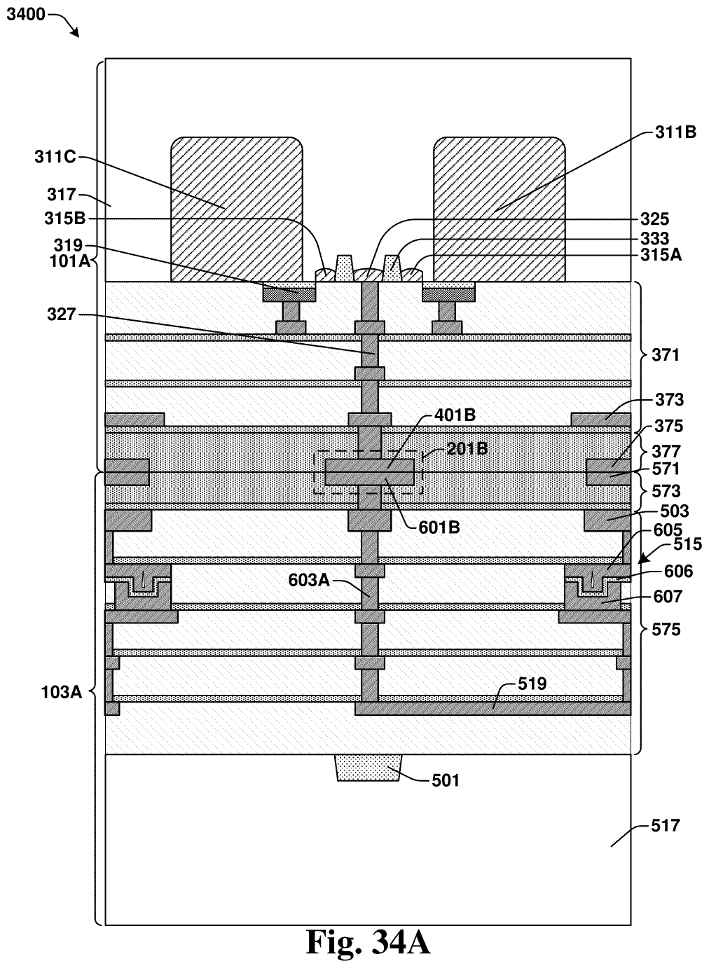

FIG. 33 provides a plan view 3300 corresponding to FIG. 32. As shown by the plan view 3300, the dummy contact pads 571 form rows 3301 between the rows 3303 that contains the contact pads 601A and 601B. The dummy contact pads 571 combine with the contact pads 601A and 601B to form a regular grid so that the dummy contact pads 571 prevent dishing during the CMP. As shown in the plan view 3300, the V_{dd} rails 503 run parallel to the rows 3303 and are disposed between the rows 3303. The positioning of the V_{dd} rails 503 avoids noise related to inductive coupling with the wires that connect to the contact pads 601A and 601B.

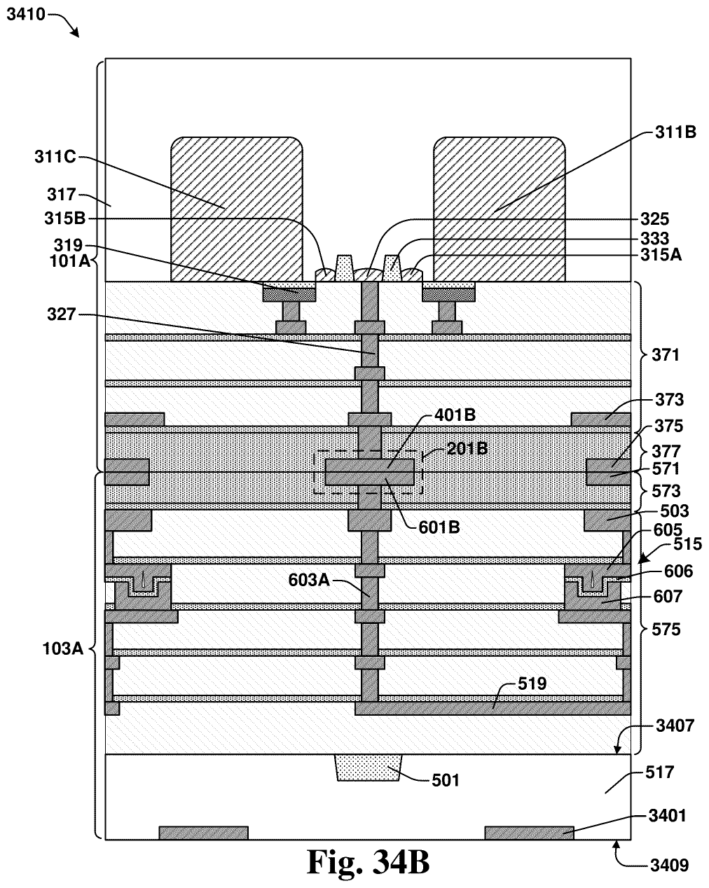

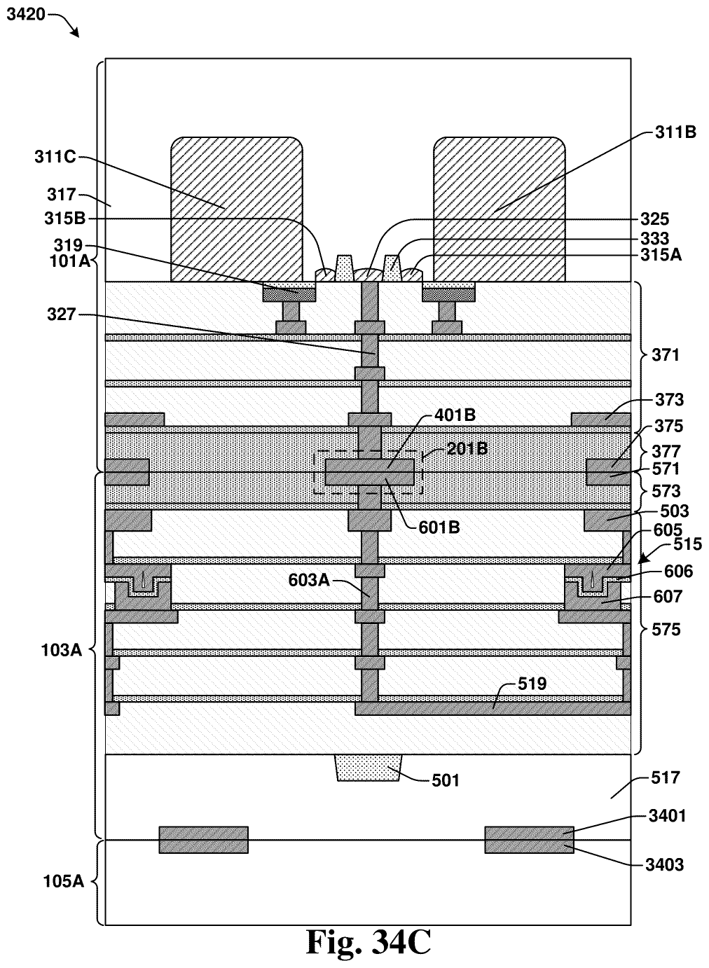

As shown by the cross-sectional view 3400 of FIG. 34A, the first wafer 101A and the second wafer 103A are aligned and bonded together. The bonding may be metal-to-metal bonding, dielectric-to-dielectric bonding, or both metal-to-metal and dielectric-to-dielectric (hybrid) bonding. The contact pad 401B is brought into abutment with the contact pad 601B to form the second connection structure 201B.

As shown by the cross-sectional view 3410 of FIG. 34B, the semiconductor substrate 517 of the second wafer 103A may be thinned from the back side 3409. The semiconductor substrate 517 may be thinned by etching, mechanical grinding, CMP, the like, or any other suitable process. After thinning, through substrate vias (TSVs, not show) may be formed. The TSVs may connect contact pads 3401, which are formed on the back side 3409, to structures on the front side 3407 such as the metal interconnect structure 575 and the row select transistor source region 521 (see FIG. 5).

As shown by the cross-sectional view 3420 of FIG. 34C, the third wafer 105A and the second wafer 103A are aligned and bonded together. The bonding may be metal-to-metal bonding, dielectric-to-dielectric bonding, or both metal-to-metal and dielectric-to-dielectric bonding. Contact pads 3403 on the third wafer 105A may form connections with contact pads 3401 on the second wafer 103A.

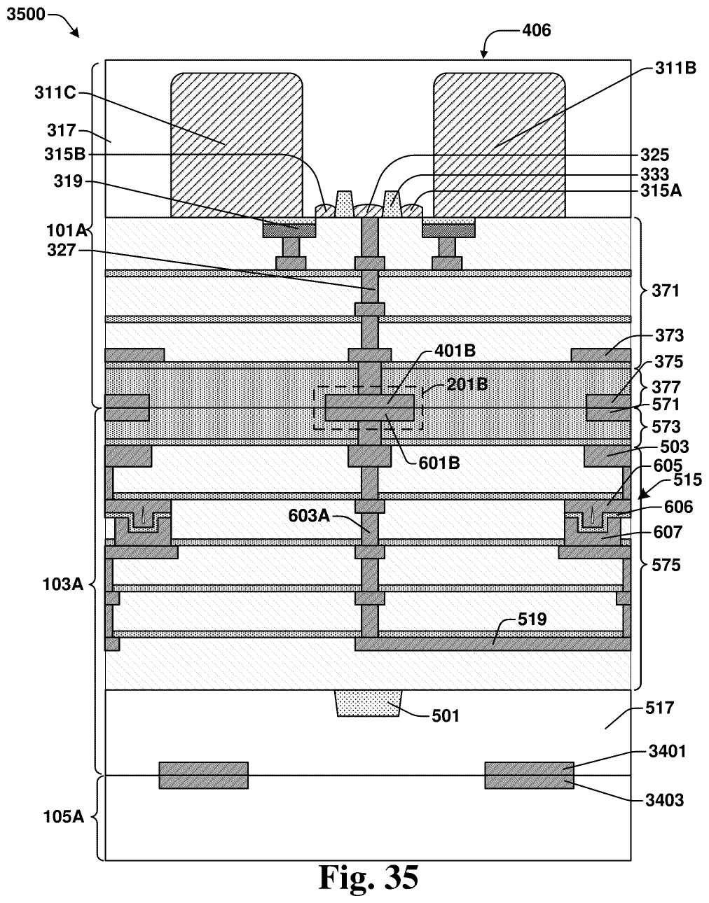

As shown by the cross-sectional view 3500 of FIG. 35, the semiconductor substrate 317 may be thinned from the back side 406. Thinning the semiconductor substrate 317 allows light to pass more easily to the photodiodes 311A-D (see FIG. 3). The semiconductor substrate 317 may be thinned from the back side 406 by etching, mechanical grinding, CMP, the like, or any other suitable process. In some embodiments, the semiconductor substrate 317 is thinned to about 5 μm or less. In some embodiments, the semiconductor substrate 317 is thinned to about 3 μm or less.

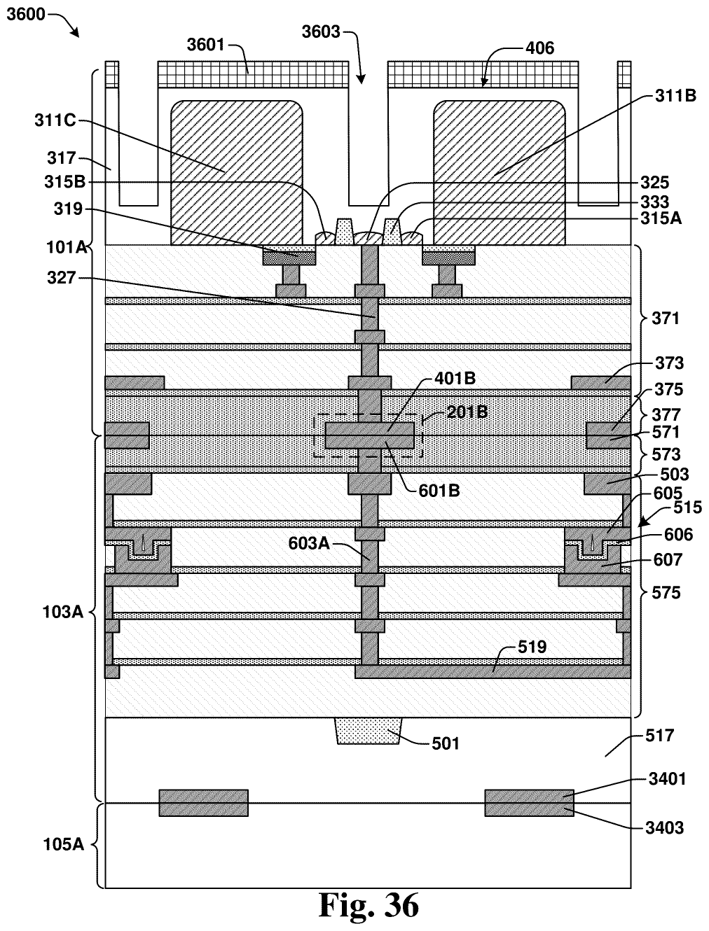

As shown by the cross-sectional view 3600 of FIG. 36, a mask 3601 may be formed and used to etch trenches 3603 in the semiconductor substrate 317. The trenches 3603 form a grid with segments between adjacent photodiodes 311A-D. The trenches 3603 have a high aspect ratio. In some embodiments, the trenches 3603 have an aspect ratio of 15:1 or greater. In some embodiments, the trenches 3603 have an aspect ratio of 20:1 or greater. In some embodiments, the trenches 3603 have an aspect ratio of 25:1 or greater. In some embodiments, the trenches 3603 abut the shallow trench isolation structures 333. In the present example, a back side deep trench isolation structure is formed. Alternatively, a front side deep trench isolation structure may be formed.

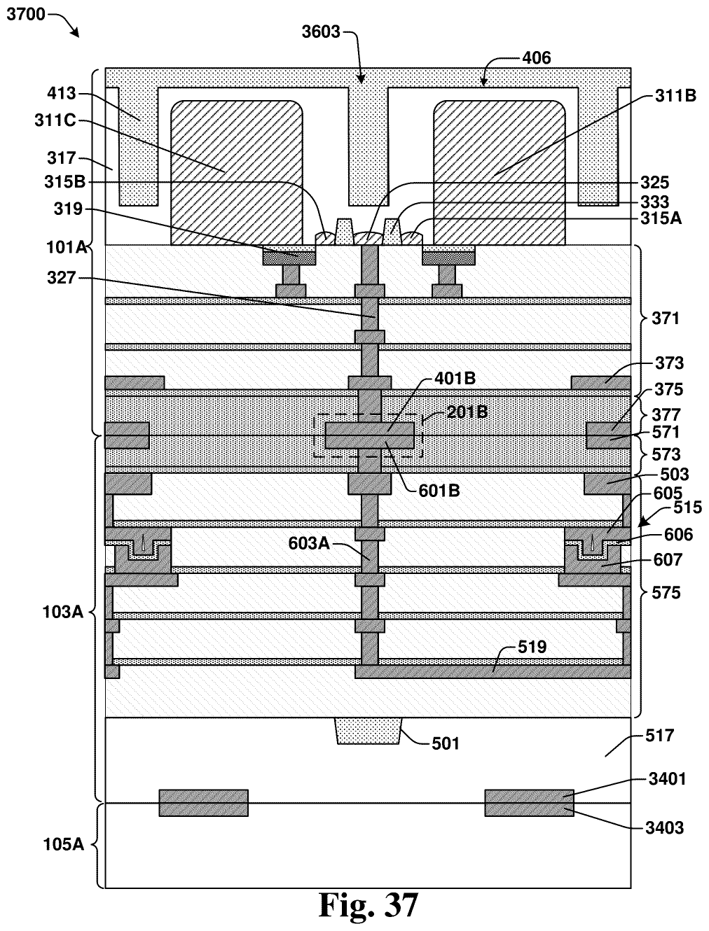

Continuing with the present example, the trenches 3603 may be filled as shown by the cross-sectional view 3700 of FIG. 37 to provide the DTI structure 413. In some embodiment, the trenches 3603 are filled with dielectric. In other embodiments, the trenches 3603 are lined with dielectric and then filled with conductive material to provide a conductive core. The conductive core may be grounded or may be coupled to a biasing voltage source.

The DTI structure 413 may comprise one or more dielectric layers. As these layers are deposited in the trenches 3603, they also deposit on the back side 406. Some of these layers may be thicker on the back side 406 depending on the condition the deposition processes with which they are formed.

In some embodiments, the trenches 3603 are lined with a high-K dielectric layer. The high-k dielectric passivates defects by forming an electric field that accumulates holes along the internal sidewalls, thereby passivating charge carriers (e.g., electrons). The high-K dielectric layer may be or comprise, for example, hafnium oxide (HfO₂), hafnium silicon oxide (HfSiO), hafnium silicon oxynitride (HfSiON), hafnium tantalum oxide (HfTaO), hafnium titanium oxide (HfTiO), hafnium zirconium oxide (HfZrO), hafnium oxide aluminum oxide (HfO₂—Al₂O₃), zirconium oxide (ZrO₂), tantalum oxide (Ta₂O₅), aluminum oxide (Al₂O₃), yttrium oxide (Y₂O₃), lanthanum oxide (La₂O₃), strontium titanium oxide (SrTiO₃), or the like and may have a thickness in the range from 5 to 50 Angstroms, for example. The high-K dielectric layer may be deposited by ALD, CVD, PVD, the like, or any suitable process.

After lining, the trenches 3603 may be filled with an oxide such as silicon dioxide (SiO₂), tantalum pentoxide (Ta₂O₅), or the like. The fill may be deposited by ALD, CVD, PVD, the like, or any suitable process. In some embodiments, the oxide includes at least a layer of tantalum pentoxide or the like. Tantalum pentoxide has a refractive index between that of silicon (Si) and that of silicon dioxide. According, a layer of tantalum pentoxide can reduce reflections. The DTI structure 413 may be planarized on the back side 406. Planarization may be by CMP, the like, or any other suitable process. Planarization provides a level surface on which to build the subsequent structure.

As shown by the cross-sectional view 3700 of FIG. 37, additional dielectric layers and the back side metal grid 411 may be formed over the back side 406. The back side metal grid 411 may have any suitable composition and thickness. The back side metal grid 411 may comprise aluminum (Al), copper (Cu), tungsten (W), the like, or any other suitable material.

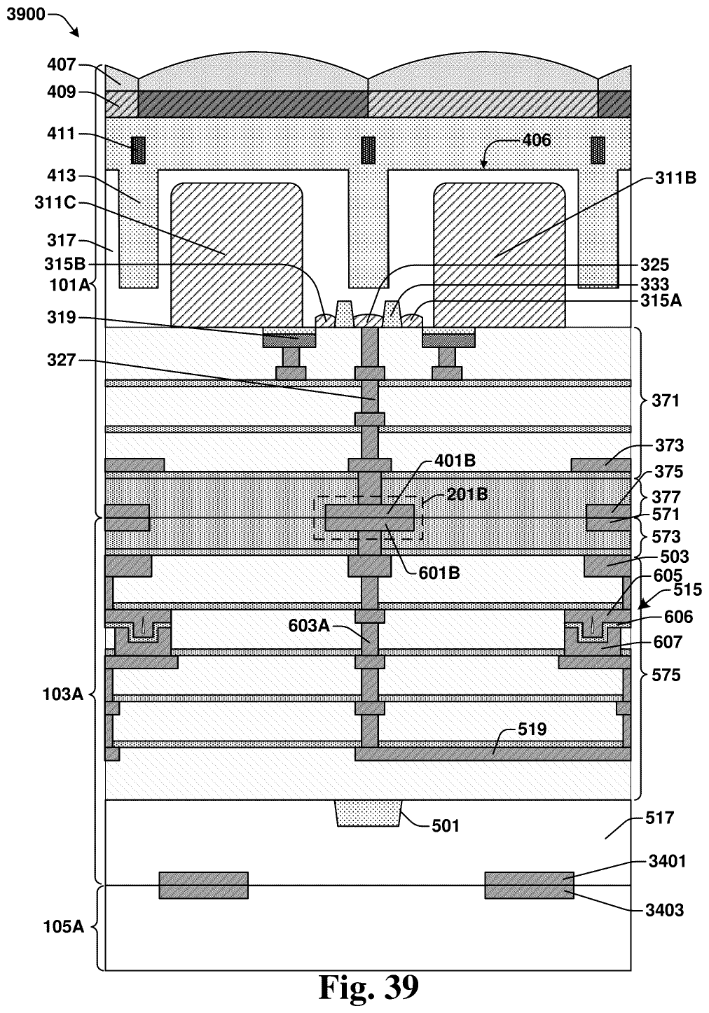

As shown by the cross-sectional view 3900 of FIG. 39, the color filters 409 and the microlenses 407 may then be formed. The color filters 409 may include red, green, and blue color filters. Other color combinations, such as cyan, yellow, and magenta, may be used instead. The color filters 409 may be in a Bayer pattern or some other pattern. The process may conclude with wafer dicing and packaging.

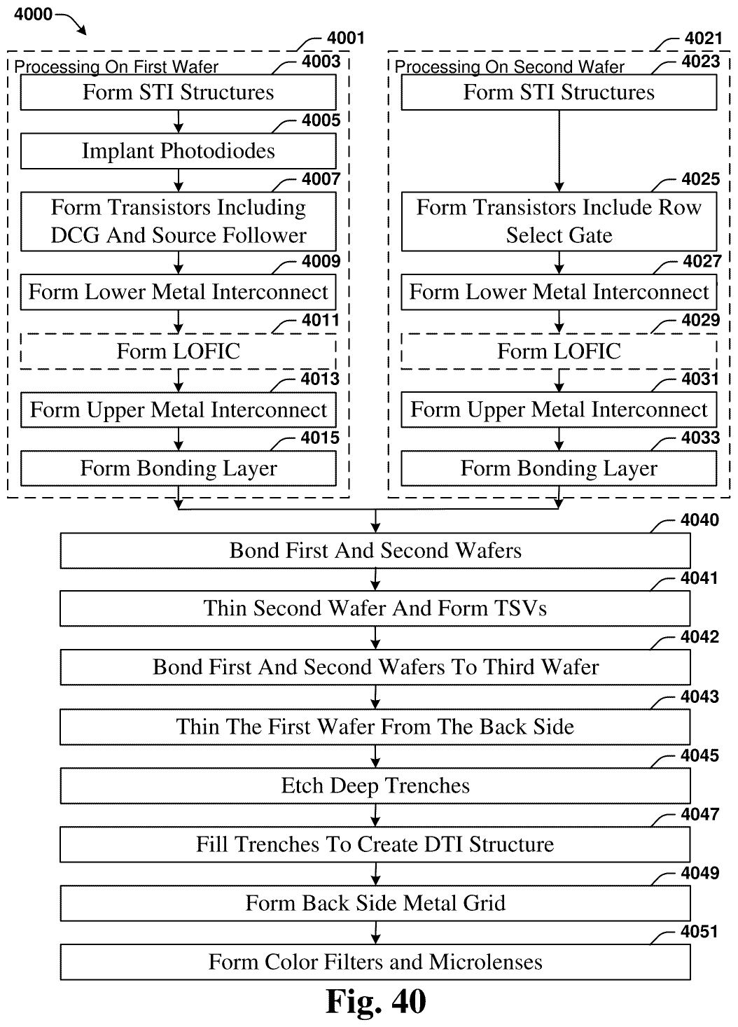

FIG. 40 provides a flow diagram for a process 4000 of forming an image sensor of the present disclosure. While the process 4000 is illustrated and described below as a series of acts or events, it will be appreciated that the illustrated ordering of such acts or events is not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The process 4000 begins with a group of acts 4001 which are performed on a first wafer and a group of acts 4021 which are performed on a second wafer. The acts 4001 may be performed before, after, or simultaneously with the group of acts 4021.

Act 4003 is forming STI structures on the first wafer. The cross-sectional view 1400 of FIG. 14 provides an example. Act 4005 is implanting dopants to form photodiodes. The cross-sectional view 1500 of FIG. 15 provides an example. Forming the photodiodes may include a plurality of dopant implantations some of which may be carried out earlier or later in the sequence of acts 4001. For example, photodiode formation may begin with a deep n-well implant made using high energy ions and without a mask.

Act 4007 is forming transistors on the front side. These include transfer gates, DCG gates, and source followers. The cross-sectional views 1600-1700 of FIGS. 16-17 provide an example. Acts 4009-4013 are back-end-of-line (BEOL) processing that forms a metal interconnect structure over a front side of the first wafer. The cross-sectional view 1800 of FIG. 18 provides an example. Act 4011 is an optional step of forming a LOFIC within the a metal interconnect structure. The cross-sectional views 2500-3000 of FIGS. 25-30 provide an example of how the LOFIC may be formed. Act 4015 is forming a bonding layer. The cross-sectional views 1900-2100 of FIGS. 19-21 and the plan view 2200 of FIG. 22 provide an example.

Act 4023 is forming STI structures on the second wafer. The cross-sectional view 2300 of FIG. 23 provides an example. Act 4025 is forming transistors on the second wafer. The transistor on the second wafer include at least row select transistors. Acts 4027 is forming the lower portion of a metal interconnect structure on the second wafer. The cross-sectional view 2400 of FIG. 24 provides an example. Act 4029 is an optional step of forming a LOFIC within the a metal interconnect structure. The cross-sectional views 2500-3000 of FIGS. 25-30 and the plan view 2200 of FIG. 22 provide an example of how the LOFIC may be formed. Acts 4031 is forming the upper portion of a metal interconnect structure on the second wafer. The cross-sectional view 3100 of FIG. 31 provides an example. Act 4033 is forming a bonding layer. The cross-sectional view 3200 of FIG. 32 provides an example.

Act 4040 is aligning the first and second wafers and bonding them together through their respective bonding layers. The cross-sectional view 3400 of FIG. 34A provides an example.

Act 4041 is thinning the second wafer from the back side, forming TSVs through the second wafer's substrate, and forming contact pads on the back side. The cross-sectional view 3410 of FIG. 34B provides an example. Act 4042 is bonding the second wafer to the third wafer so that the first, second, and third wafers are all bonded together. The cross-sectional view 3420 of FIG. 34C provides an example.

Act 4043 is thinning the first wafer from the back side. The cross-sectional view 3500 of FIG. 35 provides an example. Act 4045 is etching deep trenches in the back side. The cross-sectional view 3600 of FIG. 36 provides an example. Act 4047 is filling the trenches to provide a DTI structure. The cross-sectional view 3700 of FIG. 37 provides an example. The trenches may be lined with one or more layers of high-K dielectric and then filled with another dielectric. Alternatively, the trenches may be filled with a conductive material after being lined with dielectric. Another alternative is to form a front side DTI structure rather than a back side DTI structure.

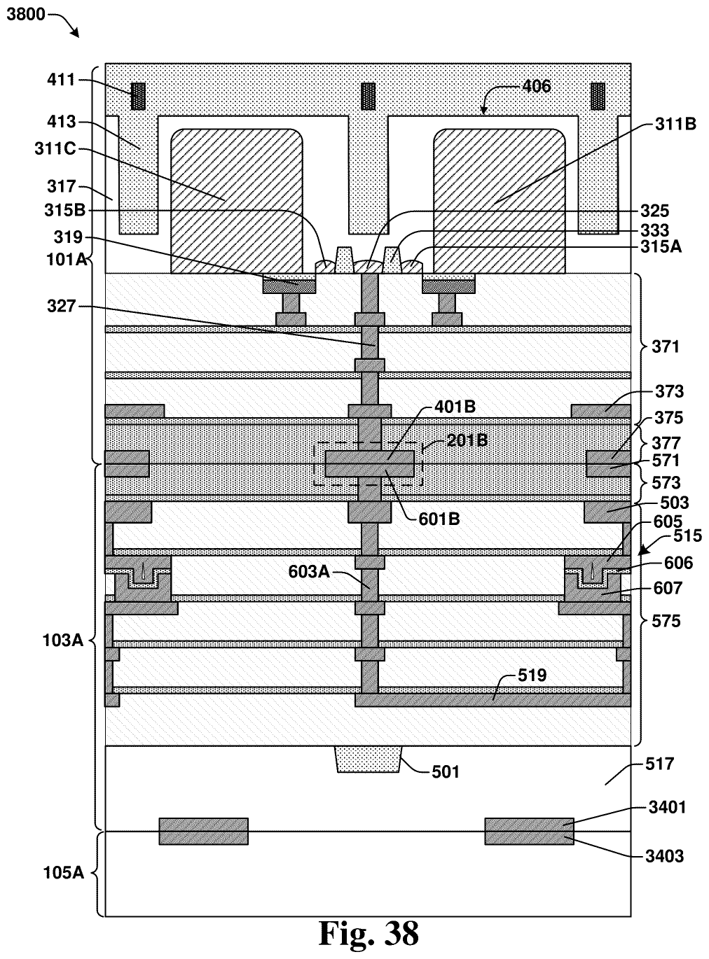

Act 4049 is forming a back side metal grid. The cross-sectional view 3800 of FIG. 38. Act 4051 is additional processing that completes the formation of an image sensor. This may include forming color filters and microlenses. The cross-sectional view 3900 of FIG. 39 provides an example.

Some aspects of the present disclosure relate to an image sensor that a photodetector comprising a photosensitive area, a floating diffusion node, a transfer gate, a source follower, a row select transistor, a first dual conversion gain transistor, and a reset transistor. The photosensitive area, the transfer gate, the source follower, and the first dual conversion gain transistor are on a first die. The row select transistor is on a second die. The two dies are bonded together, and the source follower is connected to the row select transistor through the metal interconnect structures of the two dies.

In some embodiments, opening the first dual conversion gain transistor electrically isolates the floating diffusion node form the second die. In some embodiments, the photodetector further comprises a first LOFIC which is on the second die together with the reset transistor. In some embodiments, the photodetector further comprises a second LOFIC and a second dual conversion gain transistor. The second LOFIC is on the first die and the second dual conversion gain transistor is on the second die.

In some embodiments, the photodetector comprises two contact pads on the first die interfacing with two contact pads on the second die. In some embodiments, the two contact pads on the first die are in an array comprising active contact pads and dummy contact pads. The active contacts pads are in first rows, the dummy contact pads are in second rows, and the first rows are interleaved with the second rows.

In some embodiments, the first LOFIC is a three-dimensional metal-insulator-metal capacitor. In some embodiments, the first LOFIC is in horizontal alignment with a V_{dd} rail in the second metal interconnect structure so that the first LOFIC is directly between the V_{dd} rail and the second die.

In some embodiments, the photodetector further comprises an LOFIC on the first die coupled to the floating diffusion node through the first dual conversion gain transistor. In some embodiments, the photosensitive area is one of four photosensitive areas coupled to the floating diffusion node through four respective transfer gates. In some embodiments, the source follower and the first dual conversion gain transistor are aligned in a row, a first two of the four photosensitive areas are on one side of the row, and a second two of the four photosensitive areas are on an opposite side of the row. In some embodiments, a shallow trench isolation structure has segments between the row and a respective two of the four photosensitive areas on either side of the row. In some embodiments, there is a V_{dd} rail on the first die extending parallel to the row. The V_{dd} rail is connected to a drain of the source follower.

In some embodiments, the image sensor includes a back side deep trench isolation structure having segments surrounding the photosensitive area. In some embodiments, the floating diffusion node includes a wire in a first metallization layer on the first die, but the floating diffusion node is electrically isolated from higher metallization layers when the first dual conversion gain transistor is open.

Some aspects of the present disclosure relate to a photodetector including a photodiode in a first die, a floating diffusion node, a transfer gate between the floating diffusion node and the photodiode, and a plurality of additional transistors including a first transistor on the first die and a second transistor on a second die. The floating diffusion node is confined to the first die when the first transistor is open. In some embodiments, the photodetector includes an LOFIC on the second die and the floating diffusion node is coupled to the LOFIC through the first transistor.

Some aspects of the present disclosure relate to a method of making an image sensor. The method includes forming a photodiode and a floating diffusion region on a first wafer. A transfer gate, a source follower, and a first dual conversion gain transistor are also formed on the first wafer. The transfer gate is configured to selectively couple the photodiode to the floating diffusion region. A first metal interconnect structure is formed over the first wafer. The first metal interconnect structure couples the floating diffusion region to a gate of the source follower and to a source side of the first dual conversion gain transistor. The method further includes forming a row select transistor on a second wafer and a second metal interconnect structure over the second wafer. The first wafer and the second wafer are bonded so that the first metal interconnect structure and the second metal interconnect structure are facing. The bonding couples a drain side of the row select transistor to a source side of the source follower. The first wafer is thinned and microlenses are formed on the first wafer. In some embodiments, the method further includes forming a first 3D-MIM capacitor in the second metal interconnect structure. One or more transistors, including the first dual conversion gain transistor, selectively couple the first 3D-MIM to the floating diffusion region. In some embodiments, a second dual conversion gain transistor is formed on the second wafer and the one or more transistors include the second dual conversion gain transistor and a second 3D-MIM capacitor is formed in the first metal interconnect structure. The first dual conversion gain transistor selectively couples the second 3D-MIM capacitor to the floating diffusion region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. An image sensor, comprising:
a first die comprising a first semiconductor substrate and a first metal interconnect structure;
a second die comprising a second semiconductor substrate and a second metal interconnect structure, wherein the second die is bonded to the first die; and
a photodetector comprising a photosensitive area, a floating diffusion node, a transfer gate, a source follower, a row select transistor, a first dual conversion gain transistor, and a reset transistor;
wherein the photosensitive area, the transfer gate, the source follower, and the first dual conversion gain transistor are on the first die and the row select transistor is on the second die; and
the source follower is connected to the row select transistor through the first metal interconnect structure and the second metal interconnect structure.

2. The image sensor of claim 1, wherein opening the first dual conversion gain transistor electrically isolates the floating diffusion node from the second die.

3. The image sensor of claim 1, wherein:
the photodetector further comprises a first lateral overflow integration capacitor (LOFIC); and
the first LOFIC and the reset transistor are on the second die.

4. The image sensor of claim 3, wherein:
the photodetector further comprises a second LOFIC and a second dual conversion gain transistor; and
the second LOFIC is on the first die and the second dual conversion gain transistor is on the second die.

5. The image sensor of claim 3, wherein the photodetector comprises two contact pads on the first die interfacing with two contact pads on the second die.

6. The image sensor of claim 5, wherein the two contact pads on the first die are in an array comprising active contact pads and dummy contact pads, wherein the active contacts pads are in first rows, the dummy contact pads are in second rows, and the first rows are interleaved with the second rows.

7. The image sensor of claim 3, wherein the first LOFIC is a three-dimensional metal-insulator-metal capacitor.

8. The image sensor of claim 7, wherein the first LOFIC is in horizontal alignment with a V_{dd} rail in the second metal interconnect structure so that the first LOFIC is between the V_{dd} rail and the second die.

9. The image sensor of claim 1, wherein:
the photodetector further comprises an LOFIC coupled to the floating diffusion node through the first dual conversion gain transistor; and
the LOFIC is on the first die.

10. The image sensor of claim 1, wherein the photosensitive area is one of four photosensitive areas coupled to the floating diffusion node through four respective transfer gates.

11. The image sensor of claim 10, wherein the source follower and the first dual conversion gain transistor are aligned in a row, a first two of the four photosensitive areas are on one side of the row, and a second two of the four photosensitive areas are on an opposite side of the row.

12. The image sensor of claim 11, further comprising a shallow trench isolation structure comprising segments between the row and a respective two of the four photosensitive areas on either side of the row.

13. The image sensor of claim 11, further comprising a V_{dd} rail on the first die extending parallel to the row, wherein the V_{dd} rail is connected to a drain of the source follower.

14. The image sensor of claim 1, further comprising a back side deep trench isolation structure having segments surrounding the photosensitive area.

15. The image sensor of claim 1, wherein:
the first metal interconnect structure includes a first metallization layer which is closest to the first die, and a second metallization layer, which is second closest to the first die; and
the floating diffusion node includes a wire in the first metallization layer; and
the floating diffusion node is electrically isolated from the second metallization layer when the first dual conversion gain transistor is open.

16. An image sensor, comprising:
a first die comprising a first semiconductor substrate and a first metal interconnect structure;
a second die comprising a second substrate and a second metal interconnect structure, wherein the second die is bonded to the first die; and
a photodetector comprising a photosensitive area within the first substrate, a floating diffusion node, a transfer gate between the floating diffusion node and the photosensitive area, a first transistor on the first die, and a second transistor on the second die;
wherein the floating diffusion node is confined to the first die when the first transistor is open.

17. The image sensor of claim 16, further comprising an LOFIC on the second die, wherein the floating diffusion node is coupled to the LOFIC through the first transistor, the first metal interconnect structure, and the second metal interconnect structure.

18-20. (canceled)

21. An image sensor, comprising:
a first device layer comprising a first semiconductor substrate;
a first set of electrical connections formed within a first dielectric structure on the first semiconductor substrate;
a second device layer comprising a second semiconductor substrate;
a second set of electrical connections formed within a second dielectric structure on the second semiconductor substrate;
a photodiode within the first semiconductor substrate;
a first transistor on the first semiconductor substrate, wherein the first transistor is configured to control charge transfer from the photodiode to a node comprising a well in the first semiconductor substrate;
a second transistor on the first semiconductor substrate, wherein the second transistor has a source terminal connected to node, and the node is electrically isolated from the second device layer at least when the second transistor is open;
a third transistor on the first semiconductor substrate, wherein the third transistor has a gate electrode electrically connected to the node; and
a fourth transistor on the second semiconductor substrate, wherein the fourth transistor has a drain terminal electrically connected to a source terminal of the third transistor through the first and second electrical connections.

22. The image sensor of claim 21, further comprising a three-dimensional metal-insulator-metal capacitor coupled to a drain terminal of the second transistor.

23. The image sensor of claim 22, where in the three-dimensional metal-insulator-metal capacitor is disposed within the second dielectric structure.
